(19) United States
(12) Patent Application Publication
(10) Pub. No.: US 2020/0118506 A1
(43) Pub. Date: Apr. 16, 2020

(54) ACTIVE MATRIX SUBSTRATE AND DEMULTIPLEXER CIRCUIT

(71) Applicant: Sharp Kabushiki Kaisha, Sakai City, Osaka (JP)

(72) Inventor: Kaoru YAMAMOTO, Sakai City (JP)

(21) Appl. No.: 16/603,881

(22) PCT Filed: Apr. 12, 2018
(86) PCT No.: PCT/JP2018/015340

§ 371 Date: Oct. 9, 2019

(30) Foreign Application Priority Data
Apr. 13, 2017 (JP) 2017-080050

(51) Int. Cl. G09G 3/36; H01L 27/12

(52) U.S. Cl. CPC G09G 3/3648; G09G 2310/0297; H01L 27/124; H01L 27/1225

(57) ABSTRACT

An active matrix substrate includes a demultiplexer circuit DMX_B having a plurality of unit circuits and a plurality of control signal trunk lines (SW1, SW2), each of the plurality of unit circuits distributes a video signal from one video signal line to n (n is an integer of 2 or more) source bus lines, each of the plurality of unit circuits includes at least n DMX circuit thin-film transistors (TFTs) (T1a to T1b), n branch wiring lines (B1a, B1b) connected to the video signal line (DO1), and the n source bus lines (SL1, SL3), each of the DMX circuit TFTs includes a lower gate electrode and an upper gate electrode, one of the upper gate electrode and the lower gate electrode is a front gate electrode (FG) to which a control signal is supplied from one of the control signal trunk lines, and the other thereof is a back gate electrode (BG) to which a signal different from the control signal is supplied, the drain electrode of each of the DMX circuit TFTs is electrically connected to one of the source bus lines, the source electrode is electrically connected to one of the branch wiring lines, and the back gate electrode is electrically connected to the video signal line (DO1).

### TECHNICAL FIELD

The present invention relates to an active matrix substrate having a demultiplexer circuit and the demultiplexer circuit.

### BACKGROUND ART

An active matrix substrate that is used in a liquid display device or the like has a display area that has multiple pixels and an area (a non-display area or a frame area) other than the display area. Every pixel in the display area includes a switching element such as a thin-film transistor (hereinafter, referred to as “TFT”). As such a switching element, a TFT (hereinafter, referred to as “amorphous silicon TFT”) of which an active layer is an amorphous silicon film, or a TFT (hereinafter, referred to as “polycrystalline silicon TFT”) of which an active layer is a polycrystalline silicon film has been widely used in the related art.

It has been proposed that instead of amorphous silicon or polycrystalline silicon, an oxide semiconductor is used as a material of the active layer of the TFT. Such a TFT is referred to as “oxide semiconductor TFT”. The oxide semiconductor has higher mobility than the amorphous silicon. For this reason, it is possible that the oxide semiconductor TFT operates at a higher speed than the amorphous silicon TFT.

In some cases, a peripheral circuit such as a drive circuit is monolithically (integrally) formed in a non-display area of the active matrix substrate. By monolithically forming the drive circuit, narrowing-down of the non-display area or cost reduction that results from simplifying a mounting process is realized. For example, in some cases, in the non-display area, a gate driver circuit is monolithically formed, and a source driver circuit is mounted using Chip on Glass (COG).

It is proposed that in a device, such as a smartphone, narrowing-down of which frame is highly desirable, in addition to the gate driver, a demultiplexer circuit, such as a source switch (source shared driving (SSD)) circuit, is monolithically formed (for example, PTL 1 and PTL 2). The SSD circuit is a circuit that distributes video data from one video signal line that runs from each terminal of the source driver, to multiple source lines. By mounting the SSD circuit, an area (a terminal portion- wiring formation area) in which a terminal portion and wiring are formed, of the non-display area can be further narrowed. Furthermore, the number of outputs from the source driver can be reduced, and a circuit scale can be decreased. Because of this, the cost of a driver IC can be reduced.

A peripheral circuit such as the drive circuit or the SSD circuit includes a TFT. In the present specification, a TFT that is positioned as a switching element in each pixel in the display area is referred to as “pixel TFT” and a TFT that constitutes the peripheral circuit is referred to as “circuit TFT”. In addition, among circuit TFTs, a TFT that is used as a switching element in a demultiplexer circuit (SSD circuit) is referred to as “DMX circuit TFT”.

### CITATION LIST

### Patent Literature

PTL 1: International Publication No. 2011/118079

PTL 2: Japanese Unexamined Patent Application Publication No. 2010-102266

### SUMMARY OF INVENTION

### Technical Problem

High reliability is required for the DMX circuit TFT. Particularly, when an oxide semiconductor TFT is used as the DMX circuit TFT, since a threshold voltage Vth varies due to the voltage stress applied between the source and the drain in the oxide semiconductor TFT, TFT characteristics may deteriorate with time. Furthermore, a higher current driving power may be required for the DMX circuit TFT depending on write conditions.

Embodiments of the present invention have been made in view of the above circumstances, and it is an object thereof to provide an active matrix substrate provided with a demultiplexer circuit including a TFT capable of enhancing reliability and/or driving power.

### Solution to Problem

An active matrix substrate according to an embodiment of the present invention has a display area which includes multiple pixels and a non-display area provided in a vicinity of the display area. The active matrix substrate includes a substrate, a demultiplexer circuit (DMX circuit) disposed in the non-display area and supported on the substrate, a plurality of source bus lines that extends in a first direction in the display area, and a plurality of gate bus lines that extends in a second direction intersecting the first direction. The demultiplexer circuit includes a plurality of unit circuits and a plurality of control signal trunk lines. Each of the plurality of unit circuits distributes a video signal from one of a plurality of video signal lines to n (n is an integer of 2 or more) source bus lines of the plurality of source bus lines, each of the plurality of unit circuits includes at least n DMX circuit thin-film transistors (TFTs), n branch wiring lines connected to the video signal line, and the n source bus lines. Each of the DMX circuit TFTs includes a lower gate electrode, a semiconductor layer disposed on the lower gate electrode with a gate insulation layer in between, a source electrode and a drain electrode electrically connected to the semiconductor layer, and an upper gate electrode disposed on the semiconductor layer with an insulation film in between. One of the upper gate electrode and the lower gate electrode is a front gate electrode to which a control signal is supplied from one of the plurality of control signal trunk lines, and another of the upper gate electrode and the lower gate electrode is a back gate electrode to which a signal different from the control signal is supplied. The drain electrode is electrically connected to one of the n source bus lines, the source electrode is electrically connected to one of the n branch wiring lines, and the back gate electrode is electrically connected to the video signal line.

In one embodiment, each of the plurality of unit circuits further includes n control signal branch lines and each of the n control signal branch lines is electrically connected to one of the plurality of control signal trunk lines, the demultiplexer circuit includes a plurality of sub circuits, each of the sub circuits includes at least a first unit circuit and a second unit circuit among the plurality of unit circuits, and in each of the sub circuits, the n control signal branch lines in the first unit circuit and the second unit circuit are common.

In one embodiment, in each of the sub circuits, the n source bus lines of the first unit circuit and the n source bus lines of the second unit circuit are alternately arranged one by one in the second direction in the display area.

In one embodiment, the front gate electrode of each of the DMX circuit TFTs is a part of one of the n control signal branch lines, the source electrode is a part of one of the n branch wiring lines and the drain electrode is a part of one of the n source bus lines, and in each of the plurality of unit circuits, the n control signal branch lines, the n branch wiring lines and the n source bus lines all extend in the first direction.

In one embodiment, in each of the sub circuits, a first unit circuit forming area where the at least n DMX circuit TFTs of the first unit circuit are formed is positioned between a second unit circuit forming area where the at least n DMX circuit TFT of the second unit circuit are formed and the display area.

In one embodiment, in each of the sub circuits, one of the at least n DMX circuit TFTs in the first unit circuit and one of the at least n DMX circuit TFT in the second unit circuit are connected to an identical control signal branch line, and are disposed on the identical control signal branch line at an interval.

In one embodiment, the plurality of source bus lines are arranged in the second direction from one end, each of the sub circuits includes a first source bus line, a second source bus line, a third source bus line and a fourth source bus line, which are arranged at an Nth(N is a natural number) column, an (N+1)th column, an (N+2)th column, and an (N+3)th column from the one end, respectively, the first source bus line and the third source bus line are electrically connected to one of the plurality of video signal lines via the first unit circuit, and the second source bus line and the fourth source bus line are electrically connected to another one of the plurality of video signal lines via the second unit circuit.

In one embodiment, in each of the sub circuit, when viewed in a direction normal to the substrate, one of the at least n DMX circuit TFTs of the first unit circuit is disposed between the second source bus line and the fourth source bus line.

In one embodiment, each of the at least n DMX circuit TFTs includes a plurality of TFTs arranged in the first direction and connected in parallel to each other.

In one embodiment, a back gate electrode is common to the plurality of TFTs, and when viewed in a direction normal to the substrate, the back gate electrode in common extends in the first direction.

In one embodiment, the plurality of control signal trunk lines includes n first control signal trunk lines and n second control signal trunk lines, and each of the n first control signal trunk lines is supplied with a control signal identical with a control signal of one of the n second control signal trunk lines, and the n control signal branch lines in a part of the plurality of unit circuits are electrically connected to the n first control signal trunk lines, and the n control signal branch lines in another part of the plurality of unit circuits are electrically connected to the n second control signal trunk lines.

In one embodiment, the semiconductor layer is an oxide semiconductor layer.

In one embodiment, the oxide semiconductor layer includes an In—Ga—Zn—O-based semiconductor.

In one embodiment, the In—Ga—Zn—O-based semiconductor includes a crystalline portion.

A demultiplexer circuit according to another embodiment of the present invention includes a plurality of unit circuits and a plurality of control signal trunk lines. Each of the plurality of unit circuits distributes a video signal from one of a plurality of video signal lines to n (n is an integer of 2 or more) source bus lines. Each of the plurality of unit circuits includes at least n DMX circuit TFTs, n branch wiring lines connected to the video signal line, and the n source bus lines. Each of the DMX circuit TFTs includes a lower gate electrode, a semiconductor layer disposed on the lower gate electrode with a gate insulation layer in between, a source electrode and a drain electrode electrically connected to the semiconductor layer, and an upper gate electrode disposed on the semiconductor layer with an insulation film in between. One of the upper gate electrode and the lower gate electrode is a front gate electrode to which a control signal is supplied from one of the plurality of control signal trunk lines, and another of the upper gate electrode and the lower gate electrode is a back gate electrode to which a signal different from the control signal is supplied. The drain electrode is electrically connected to one of the n source bus lines, the source electrode is electrically connected to one of the n branch wiring lines, and the back gate electrode is electrically connected to the video signal line.

### Advantageous Effects of Invention

According to the embodiment of the present invention, a demultiplexer circuit including a thin-film transistor capable of enhancing reliability and/or driving power, and an active matrix substrate including the demultiplexer circuit are provided.

### BRIEF DESCRIPTION OF DRAWINGS

FIG. 1 is a schematic diagram illustrating an example of a structure of an active matrix substrate 1000 in plan view according to an embodiment of the present invention;

FIG. 2 is a diagram illustrating a configuration and operation of a demultiplexer circuit DMX)A that is integrally formed on the active matrix substrate 1000;

FIG. 3(a) is a diagram illustrating a configuration of another demultiplexer circuit DMX)B, which illustrates one sub circuit 200 in the demultiplexer circuit DMX_B and FIG. 3(b) is a diagram (timing chart) illustrating an example of a signal waveform of the sub circuit 200;

FIGS. 4(a) and 4(b) are a plan view and a sectional diagram, respectively, that illustrates a thin-film transistor (DMX circuit TFT) 10 used in the demultiplexer circuit DMX;

FIGS. 5(a) and 5(b) are sectional diagrams that illustrate an evaluation TFT 10d having a double gate structure and evaluation TFT 10s having a single gate structure, respectively;

FIG. 6 is a diagram illustrating a relationship between a Vds stress application time and an on current in the double gate structure TFT 10d and the single gate structure TFT 10s;

FIG. 7(a) is a graph illustrating dependency of Vg-Id characteristics on a back gate potential Vbg and FIG. 7(b) is a graph illustrating dependency of a Vds stress breakdown voltage on a back gate potential Vbg;

FIGS. 8(a) and 8(b) are diagrams that illustrate one sub circuit 201 and one sub circuit 901 in demultiplexer circuits of Example and Comparative Example, respectively;

FIG. 9A is diagrams illustrating examples of signal waveforms and potential waveforms in sub circuits 201 and 901 of Example and Comparative Example, where FIG. 9A(a) is a diagram illustrating signal waveforms of control signals supplied from control signal trunk lines SW1 and SW2, FIG. 9A(b) is a diagram illustrating signal waveforms of video signals V1 and V2 and potential waveforms of source bus lines SL1 and SL2, and FIGS. 9A(c) and 9A(d) are diagrams illustrating a gate-source voltage Vgs and a drain-source voltage Vds of thin-film transistors T1a and T2a, respectively;

FIGS. 9B(e) and 9B(f) are diagrams that illustrate examples of back gate potentials Vbg of thin-film transistors T1a and T2a in the sub circuit 201 of Example, respectively, and FIGS. 9B(g) and 9B(h) are diagrams that illustrate examples of back gate potentials Vbg of thin-film transistors T1a and T2a in the sub circuit 901 of Comparative Example, respectively;

FIG. 10A is diagrams illustrating other examples of signal waveforms and potential waveforms in demultiplexer circuits of Example and Comparative Example, where FIG. 10A(a) a diagram illustrating signal waveforms of control signals supplied from control signal trunk lines SW1 and SW2, FIG. 10A(b) is a diagram illustrating signal waveforms of video signals V1 and V2 and potential waveforms of source bus lines SL1 and SL2, and FIGS. 10A(c) and 10A(d) are diagrams illustrating a gate-source voltage Vgs and a drain-source voltage Vds of thin-film transistors T1a and T2a, respectively;

FIGS. 10B(e) and 10B(f) are diagrams that illustrate other examples of back gate potentials Vbg of thin-film transistors T1a and T2a in the sub circuit 201 of Example, respectively, and FIGS. 10B(g) and 10B(h) are diagrams that illustrate other examples of back gate potentials Vbg of thin-film transistors T1a and T2a in the sub circuit 901 of Comparative Example, respectively;

FIG. 11 is a plan view illustrating a layout of a unit circuit 100 in the demultiplexer circuit DMX_A;

FIG. 12 is a plan view illustrating a layout of the demultiplexer circuit DMX_B;

FIG. 13 is a plan view illustrating a layout of the sub circuit 200A in the demultiplexer circuit DMX_B;

FIG. 14 is a plan view illustrating a layout of another sub circuit 200B in the demultiplexer circuit DMX_B;

FIG. 15 is a diagram illustrating a configuration of a sub circuit 300 of a demultiplexer circuit DMX_C;

FIG. 16 is a plan view illustrating a layout of the sub circuit 300;

FIG. 17 is a diagram illustrating configurations of sub circuits 400(1) and 400(2) of a demultiplexer circuit DMX_D; and

FIGS. 18(a) and 18(b) are a plan view of a pixel area PIX in the active matrix substrate 1000, and a sectional diagram taken along line II-II, respectively.

### DESCRIPTION OF EMBODIMENTS

### First Embodiment

An active matrix substrate according to a first embodiment will be described below with reference to the drawings. In the following, as an example, an active matrix substrate in which an SSD circuit and a gate driver are monolithically formed and a source driver is mounted will be described below. It is noted that in the active matrix substrate according to the present embodiment, a peripheral circuit including at least one TFT may be monolithically formed.

### Structure of the Active Matrix Substrate

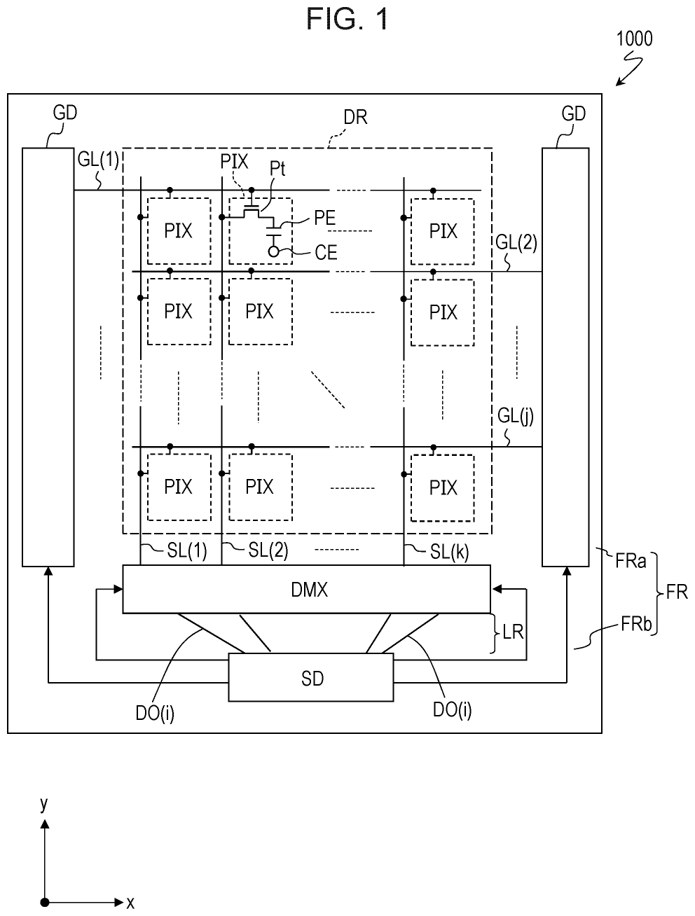

FIG. 1 is a schematic diagram illustrating an example of a structure of an active matrix substrate 1000 in plan view according to the present embodiment.

The active matrix substrate 1000 has a display area DR and an area (a non-display area or a frame area) FR other than the display area DR. The display area DR is configured with pixel areas PIX that are arranged in matrix form. The pixel area PIX (which, in some cases, is also referred to simply as “pixel”) is an area that corresponds to a pixel of a display device. The non-display area FR is an area that is positioned in the vicinity of the display area DR and does not contribute to display.

In the display area DR, a plurality of gate bus lines GL(1) to GL(j) (j is an integer of 2 or more) (hereinafter, collectively referred to as the “gate bus line GL”) extending in the x direction (also referred to as row direction or second direction), and a plurality of source bus lines SL(1) to SL(k) (k is an integer of 2 or more) (hereinafter, collectively referred to as “source bus line SL”) extending in the y direction (also referred to as column direction or first direction) are formed. Each pixel area PIX, for example, is defined by the gate bus line GL and the source bus line SL. Each of the gate bus lines GL is connected to each terminal of the gate driver GD. Each of the source bus line SL is connected to each terminal of the source driver SD.

Each pixel region PIX includes a thin-film transistor Pt and a pixel electrode PE. The thin-film transistor Pt is also referred to as a “pixel TFT”. A gate electrode of the thin-film transistor Pt is electrically connected to the corresponding gate bus line GL, a source electrode thereof is electrically connected to the corresponding source bus line SL. A drain electrode is electrically connected to the pixel electrode PE. In a case where the active matrix substrate 1000 is applied to a display device that operates in a transverse electric field mode such as a Fringe Field Switching (FFS) mode, an electrode (a common electrode) CE that is common to multiple pixels is provided in the active matrix substrate 1000. In a case where the active matrix substrate 1000 is applied to a vertical electric field mode display device, the common electrode CE is provided on a counter substrate that is disposed to face the active matrix substrate 1000 with a liquid crystal layer in between.

In the non-display area FR, for example, a gate driver GD that drives the gate bus line GL, a demultiplexer circuit DMX, and the like are provided integrally (monolithically). The demultiplexer circuit DMX functions as an SSD circuit that drives the source bus line SL in a time division manner. A source driver SD driving the bus line SL, for example, is mounted in the active matrix substrate 1000.

In an example that is illustrated, the gate drivers GD are positioned in areas FRa that are positioned on both sides of the display area DR, the source driver SD is mounted in an area FRb that is positioned under the display area DR. The demultiplexer circuit DMX is positioned between the display area DR and the source driver SD in the area FRb. A terminal portion/wiring line forming region LR, in which a plurality of terminal portions and wiring lines are formed, is between the demultiplexer circuit DMX and the source driver SD.

### Configuration and Operation of Demultiplexer Circuit DMX

In the present embodiment, a double gate structure TFT having two gate electrodes arranged with an oxide semiconductor layer in between is used as a switching element (DMX circuit TFT) of the demultiplexer circuit DMX. Of the gate electrodes, an electrode positioned on the substrate side of the oxide semiconductor layer may be referred to as a “lower gate electrode”, and an electrode positioned above the oxide semiconductor layer may be referred to as an “upper gate electrode”. One of the upper gate electrode and the lower gate electrode is a front gate electrode FG to which a control signal for controlling the on/off operation of the DMX circuit TFT is supplied, and the other is a back gate electrode BG to which a signal different from the control signal is supplied. In the present embodiment, the back gate electrode BG is electrically connected to a video signal line that supplies a video signal. That is, the back gate electrode BG is electrically connected to an output terminal (hereinafter, “V terminal”) of a source driver that supplies a video signal.

According to the present embodiment, by electrically connecting the back gate electrode BG to the V terminal side (video signal line or V terminal), the potential between the back gate and the source (hereinafter referred to as “back gate potential”) Vbg can be fixed to 0V. In this way, the breakdown voltage of the DMX circuit TFT can be improved, and the reliability can be improved. When writing to the source bus line SL is performed such that the potential of the source bus line SL is changed from a low potential (for example, a potential for displaying the lowest gradation) to a high potential (for example, a potential for displaying the highest gradation) via the DMX circuit TFT, a positive bias is applied to the back gate electrode BG of the thin-film transistor only in the initial charge of the source bus line SL. As a result, the threshold voltage of the DMX circuit TFT is effectively lowered, and thus the driving force can be increased. These effects will be described in detail later along with experimental results.

Hereinafter, the configuration and operation of the demultiplexer circuit DMX in the present embodiment will be described. Here, an example in which the upper gate electrode is used as the “back gate electrode BG” and the lower gate electrode is used as the “front gate electrode FG” will be described. It is to be noted that the lower gate electrode may be used as a back gate electrode, and the upper gate electrode may be used as a front gate electrode.

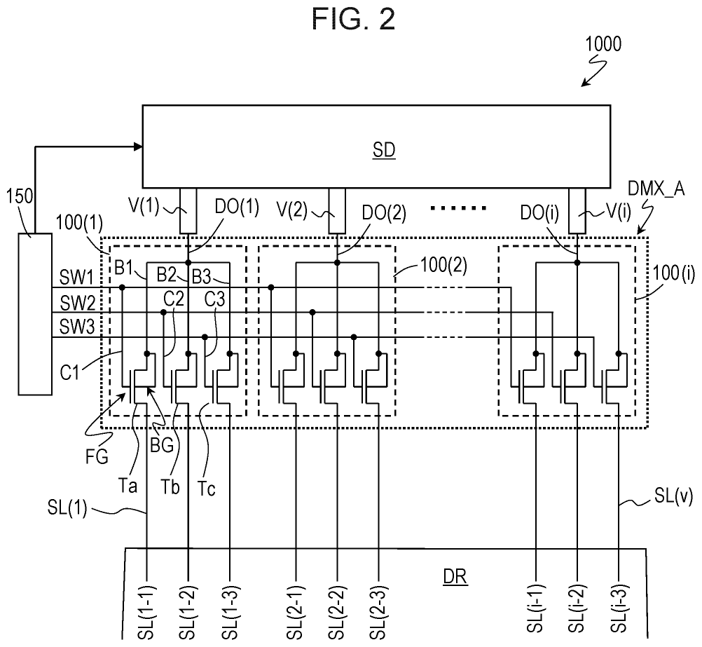

FIG. 2 is a diagram illustrating a configuration and operation of a demultiplexer circuit DMX_A on the active matrix substrate 1000 according to the present embodiment.

The demultiplexer circuit DMX_A (here, the SSD circuit) is disposed between the source driver SD and the display area DR. The demultiplexer circuit DMX_A includes a plurality of unit circuits 100 (1) to 100 (i) (i is an integer of 2 or more) (sometimes collectively referred to as “unit circuit 100”), and control signal trunk lines SW1 to SWn (n is an integer of 2 or more, here n=3). The demultiplexer circuit DMX_A and the source driver SD are controlled by a control circuit 150 provided in the non-display area FR. The control signal trunk lines SW1 to SWn are connected to the control circuit 150.

Connected to each of the output terminals V(1) to V(i) (hereinafter collectively referred to as “V terminal”) of the source driver SD is any one of multiple video signal lines, video signal lines DO(1) to DO(i) (which, in some cases, are collectively referred to as “video signal line DO”). Associated with one video signal line DO is n source bus lines SL in a group. The unit circuit 100 is provided on a per-video signal line basis between the video signal line DO and the source bus lines SL in a group. The unit circuit 100 distributes video data from one video signal line DO to n source bus lines SL.

In the present embodiment, an N-th video signal line of the multiple video signal lines DO(1) to DO(i) is defined as DO(N) (N is an integer from 1 to i), and the unit circuit 100 and the source bus line SL that are associated with the video signal line DO(N) are defined as 100(N) and SL(N−1) to SL(N−n), respectively. The source bus lines SL(N−1) to SL(N−n), for example, may be associated with R, G, and B pixels, respectively (that is, n=3).

Each unit circuit 100 (N) includes n branch wiring lines B1 to Bn connected to the video signal line DO (N), at least n (here, 3) thin-film transistors (DMX circuit TFTs) Ta to Tc, and n control signal branch lines C1 to Cn. Each of the control signal branch lines C1 to Cn (sometimes collectively referred to as “control signal branch line C”) are electrically connected to a corresponding one of the n control signal trunk lines SW1 to SWn (sometimes collectively referred to as “control signal trunk line SW”).

The thin-film transistors Ta to Tc which are the DMX circuit TFTs function as selection switches. The DMX circuit TFT is a double gate structure TFT having a front gate electrode FG and a back gate electrode BG. A source electrode of the DMX circuit TFT is electrically connected to a corresponding one of branch wiring lines B1 to Bn. A drain electrode of the DMX circuit TFT is connected to a corresponding one of the source bus lines SL(N−1) to SL(N−3). The front gate electrode FG is electrically connected to the corresponding control signal trunk line SW via the control signal branch line C. The back gate electrode BG is electrically connected to the corresponding video signal line. In the example, the back gate electrode BG is connected to the branch wiring line B to which the source electrode is connected.

A selection signal (control signal) is supplied from the corresponding control signal trunk line SW to the front gate electrode FG of the DMX circuit TFT. The control signal defines an ON duration of the selection switch within the same group and is synchronized with a time-series signal output from the source driver SD. The unit circuit 100(N) writes (performs time division driving of) data electric potential that is obtained by time-dividing an output of the video signal line DO(N), to multiple source bus lines, the source bus line SL(N−1) to the source bus line SL(N−n) in a time-series manner. Accordingly, because the number of V terminals of the source driver SD can be reduced, an area of non-display area FR can be further reduced (frame-narrowing).

It is noted that operation of a display device that uses the demultiplexer circuit DMX, a timing chart of time division driving, and the like, for example, are disclosed in Japanese Unexamined Patent Application Publication Nos. 2008-225036 and 2006-119404, International Publication No. 2011/118079 (PTL 1). For reference, the entire contents of Japanese Unexamined Patent Application Publication Nos. 2008-225036 and 2006-119404, and International Publication No. 2011/118079 are incorporated in the present specification.

The configuration, arrangement, and the like of the demultiplexer circuit in the present embodiment are not limited to the above. For example, from the control signal trunk line SW of the demultiplexer circuit, n control signal branch lines C may be provided for at least two unit circuits (hereinafter referred to as “first unit circuit” and “second unit circuit”). In the present specification, a circuit including two or more unit circuits having a common control signal branch line C is referred to as a “sub circuit”. The number of control signal branch lines C is n×number of sub circuits. Therefore, the number of control signal branch lines C when the control signal branch line C is provided for each unit circuit (n×number of unit circuits) can be reduced to ½ or less.

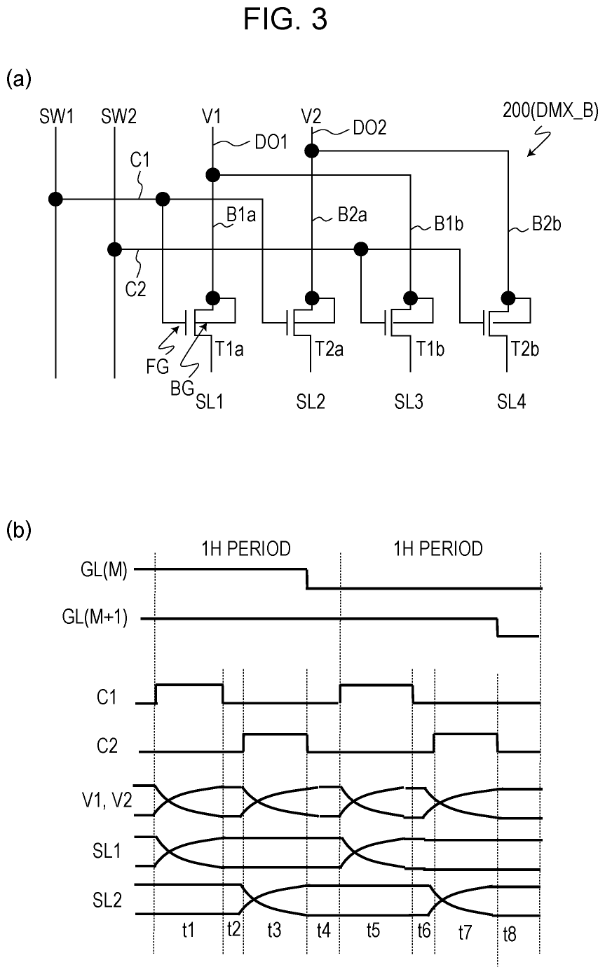

FIG. 3(a) is a diagram illustrating a configuration of another demultiplexer circuit DMX_B according to the present embodiment, which illustrates one sub circuit 200 in the demultiplexer circuit DMX_B.

The sub circuit 200 has a first unit circuit and a second unit circuit. Here, each unit circuit is associated with two source bus lines (n=2), and distributes one video signal to two source bus lines SL.

In the display area DR, a plurality of source bus lines SL extending in the y direction are arranged in the x direction. In the specification, a plurality of source bus lines SL included in one sub circuit 200 are referred to as a first source bus line SL1, a second source bus line SL2, a third source bus line SL3 and a fourth source bus line SL4, respectively, in order from one end (here, the left end).

In the example, the first unit circuit is associated with the first source bus line SL1 and the third source bus line SL3. The video signal V1 from the corresponding video signal line DO1 is distributed to the first source bus line SL1 and the third source bus line SL3 via the first unit circuit. The second unit circuit is associated with the second source bus line SL2 and the fourth source bus line SL4. The video signal V2 from the video signal line DO2 different from the first unit circuit is distributed to the second source bus line SL2 and the fourth source bus line SL4 via the second unit circuit. The first unit circuit and the second unit circuit also have common control signal branch lines C1 and C2. The control signal branch lines C1 and C2 (sometimes collectively referred to as “control signal branch line C”) are connected to the control signal trunk lines SW1 and SW2, respectively. The control signal branch line C is provided for each sub circuit.

The configuration of each unit circuit will be described more specifically. The first unit circuit includes two thin-film transistors (DMX circuit TFTs) T1a and T1b, two branch wiring lines B1a and B1b, and two control signal branch lines C1 and C2. The second unit circuit includes two thin-film transistors (DMX circuit TFTs) T2a and T2b, two branch wiring lines B2a and B2b, and control signal branch lines C1 and C2 that are common to the first unit circuit. The branch wiring lines B1a and B1b of the first unit circuit are electrically connected to the video signal line DO1, and the branch wiring lines B2a and B2b of the second unit circuit are electrically connected to the video signal line DO2. The drain electrodes of the thin-film transistors T1a and T1b of the first unit circuit are connected to the first source bus line SL1 and the third source bus line SL3, respectively, and the source electrodes thereof are connected to the branch wiring lines B1a and B1b, respectively. The drain electrodes of the thin-film transistors T2a and T2b of the second unit circuit are connected to the second source bus line SL2 and the fourth source bus line SL4, respectively, and the source electrodes thereof are connected to the branch wiring lines B2a and B2b, respectively. The front gate electrodes FG of the thin-film transistors Tia and T2a are each connected to the control signal trunk line SW1 via the control signal branch line C1. The front gate electrodes FG of the thin-film transistors T1b and T2b are each connected to the control signal trunk line SW2 via the control signal branch line C2.

n (here, two) source bus lines SL1 and SL3 associated with the first unit circuit, and n (here, two) source bus lines SL2 and SL4 associated with the second unit circuit may be arranged alternately one by one in the x direction (row direction) in the display area.

Each of the DMX circuit TFTs has a back gate electrode BG on the opposite side to the front gate electrode FG with the oxide semiconductor layer in between. The back gate electrode BG is connected to the video signal line DO (V terminal) via the corresponding branch wiring line B. Here, the back gate electrodes BG of the thin-film transistors T1a and T1b are electrically connected to the video signal line DO1 that supplies the input signal V1 via the branch wiring lines B1a and B1b, respectively. The back gate electrodes BG of the thin-film transistors T2a and T2b are electrically connected to the video signal line DO2 that supplies the input signal V2 via the branch wiring lines B2a and B2b, respectively.

Next, the operation of the sub circuit 200 will be described.

FIG. 3(b) is a diagram (timing chart) illustrating an example of signal waveforms of the gate bus line GL, the control signal trunk lines SW1 and SW2 (or the control signal branch lines C1 and C2), the video signals V1 and V2, and the first source bus line SL1 and the second source bus line SL2. Here, only the write operation portion to the Mth gate bus line GL (M) and the (M+1)th gate bus line GL (M+1) will be described. The horizontal axis represents time, the period t1 to t4 is the write time to the gate bus line GL (M) (one horizontal scanning period (1H period)), and the period t5 to t8 is the write time to the gate bus line GL (M+1) (1H period).

First, in the period t1, the control signal of the control signal trunk line SW1 becomes high level (high), and one of the two DMX circuit TFTs in each unit circuit is selected. In this example, the thin film-transistors T1a and T2a are selected, and the video signal V1 is connected to the first source bus line SL1 via the thin-film transistor T1a, and the video signal V2 is connected to the second source bus line SL2 via the thin-film transistor T2a. At this timing, the video signals V1 and V2 are each driven to the desired potential to charge the first source bus line SL1 and the second source bus line SL2.

In the period t2, the control signal of the control signal trunk line SW1 becomes low level (low) and the gates of the thin-film transistors T1a and T2a are turned off, and thus the potentials of the first source bus line SL1 and the second source bus line SL2 are determined.

In the period t3, the control signal of the control signal trunk line SW2 becomes high level, and the other DMX circuit TFT of each unit circuit is selected. In this example, the thin-film transistor T1b and the thin-film transistor T2b are selected, and the video signal V1 is connected to the third source bus line SL3 via the thin-film transistor T1b, and the video signal V2 is connected to the fourth source bus line SL4 via the thin-film transistor T2b, respectively. At this timing, the video signals V1 and V2 are each driven to the desired potential to charge the third source bus line SL3 and the fourth source bus line SL4.

Next, in the period t4, the control signal of the control signal trunk line SW2 becomes low level and the gates of the thin-film transistors T1b and T2b are turned off, and thus the potentials of the third source bus line SL3 and the fourth source bus line SL4 are determined. At this timing, the voltage of the scanning signal of the gate bus line GL (M) becomes low level, and writing of the pixel potential is completed.

The operation in the periods t5 to t8 is similar to the operation in the periods t1 to t4 described above.

### Configuration of the DMX Circuit TF

Next, an example of the configuration of the DMX circuit TFT in the present embodiment will be described. As described above, the DMX circuit TFT has a double gate structure. Here, an oxide semiconductor TFT will be described as an example, but the DMX circuit TFT may be another TFT such as a silicon semiconductor TFT. In addition, the active matrix substrate 1000 according to the present embodiment may have at least one TFT having a double gate structure as the DMX circuit TFT, and may further have a circuit TFT having a different structure.

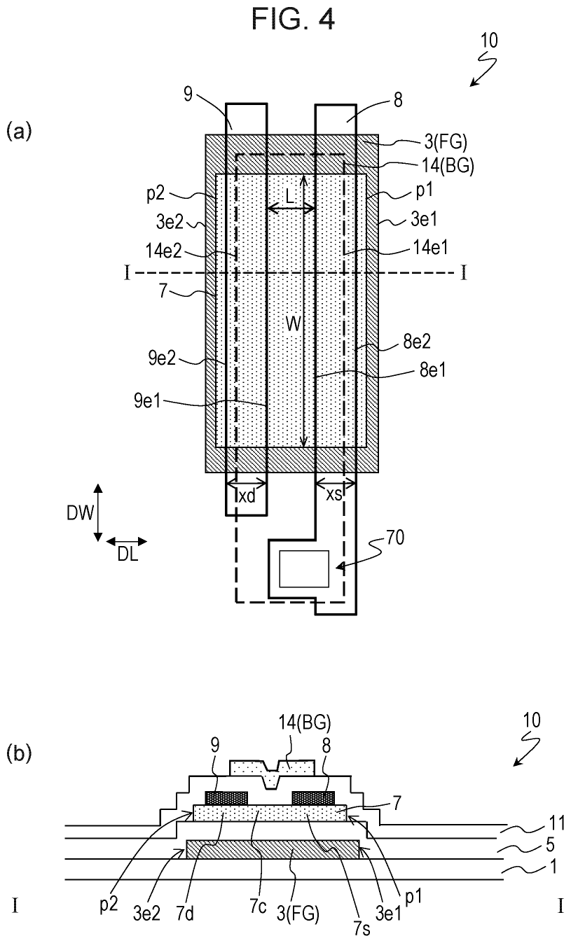

FIGS. 4(a) and 4(b) are a plan view and a sectional diagram, respectively, of the thin-film transistor 10 used for the DMX circuit TFT.

The DMX circuit TFT is supported on the substrate 1 and is formed in a non-display area. The DMX circuit TFT includes a lower gate electrode 3 disposed on the substrate 1, a gate insulation layer 5 covering the lower gate electrode 3, an oxide semiconductor layer 7, a source electrode 8, and a drain electrode 9. The oxide semiconductor layer 7 is disposed on the gate insulation layer 5 so as to at least partially overlap with the lower gate electrode 3 with the gate insulation layer 5 in between. Here, the lower gate electrode 3 is the front gate electrode FG.

The source electrode 8 is provided on the oxide semiconductor layer 7, and is in contact with a part of the oxide semiconductor layer 7. The drain electrode 9 is provided on the oxide semiconductor layer 7, and is in contact with another part of the oxide semiconductor layer 7. In the present specification, in the oxide semiconductor layer 7, a portion in contact with the source electrode 8 is referred to as a source contact area 7s, and a portion in contact with the drain electrode 9 is referred to as a drain contact area 7d. When viewed in a direction normal to the substrate 1, a region which is positioned between the source contact area 7s and the drain contact area 7d and overlaps with the lower gate electrode 3 is the “channel region 7c.” In the present embodiment, in the oxide semiconductor layer 7, when end portions facing each other in the channel length direction are referred to as p1 and p2, the source contact area 7s is disposed on the side of the end portion p1 of the channel region 7c, and the drain contact area 7d is disposed on the side of the end p2 of the channel region 7c.

The DMX circuit TFT further includes an upper gate electrode 14 as the back gate electrode BG. The upper gate electrode 14 is disposed on the oxide semiconductor layer 7 with an insulation film in between (here, inorganic insulation layer 11). When viewed in the direction normal to the substrate 1, the upper gate electrode 14 at least partially overlaps with the oxide semiconductor layer 7.

The upper gate electrode 14 is electrically connected to the source electrode 8 (or branch wiring line B). In this example, in the contact portion 70, the upper gate electrode 14 is in contact with the branch wiring line B in the opening provided in the inorganic insulation layer 11. The position and configuration of the contact portion 70 are not limited to the illustrated example.

In the specification, in a plane parallel to the substrate 1, the direction DL parallel to the direction of current flow in the channel region 7c is referred to as “channel length direction”, and the direction DW perpendicular to the channel length direction DL is referred to as “channel width direction”. In the channel region 7c, the length along the channel length direction DL is the channel length L, and the length along the channel width direction DW is the channel width W. In the present embodiment, the channel length direction DL is a direction connecting end portions p1 and p2. From the end portion p1 to the end portion p2, the source contact area 7s, the channel region 7c and the drain contact area 7d are arranged in this order in the channel length direction DL. In addition, in some cases, current may not flow in one direction in the channel region 7c, depending on the shapes and the arrangement of the lower gate electrode 3, the oxide semiconductor layer 7 and the drain contact area 7d. In such a case, a direction in which end portions p1 and p2 of the oxide semiconductor layer 7 are connected or a direction in which the source contact area 7s and the drain contact area 7d are connected at the shortest distance is referred to as the channel length direction DL.

The source electrode 8 and the drain electrode 9 may be designed to overlap with the lower gate electrode 3 when viewed in the direction normal to the substrate 1. The lengths xs and xd of the portions where the source electrode 8 and the drain electrode 9 and the lower gate electrode 3 overlap can be set in consideration of alignment accuracy. For example, even when alignment occurs in the channel length direction DL, the region (offset region) which does not overlap with any of the lower gate electrode 3, the source electrode 8, and the drain electrode 9 can be set so as not to be formed in the oxide semiconductor layer 7. The overlapping lengths xs and xd differs depending on a manufacturing device and the like, and for example, are 1.5 μm or more and 3.0 μm or less. In the example, the entire width of the source electrode 8 and the drain electrode 9 overlaps with the lower gate electrode 3, and the widths of the electrodes are overlap lengths xs and xd, respectively.

The inorganic insulation layer 11 may be disposed to be in contact with the upper surfaces of the source electrode 8 and the drain electrode 9 and the channel region 7c of the oxide semiconductor layer 7. The inorganic insulation layer 11 is located between the upper gate electrode 14 and the oxide semiconductor layer 7 and functions as a gate insulation film.

In the present embodiment, the source electrode 8 and the drain electrode 9 are formed using the same conductive layer as the source bus line SL (FIG. 1). The layer formed using the same conductive layer as the source bus line SL is referred to as a “source metal layer”. In addition, the lower gate electrode 3 is formed using the same conductive layer as the gate bus line GL (FIG. 1). The layer formed using the same conductive layer as the gate bus line GL is referred to as a “gate metal layer”.

The upper gate electrode 14 may be, for example, a transparent electrode formed using the same transparent conductive film as that of the transparent electrode (for example, pixel electrode PE and common electrode CE) disposed in the display area.

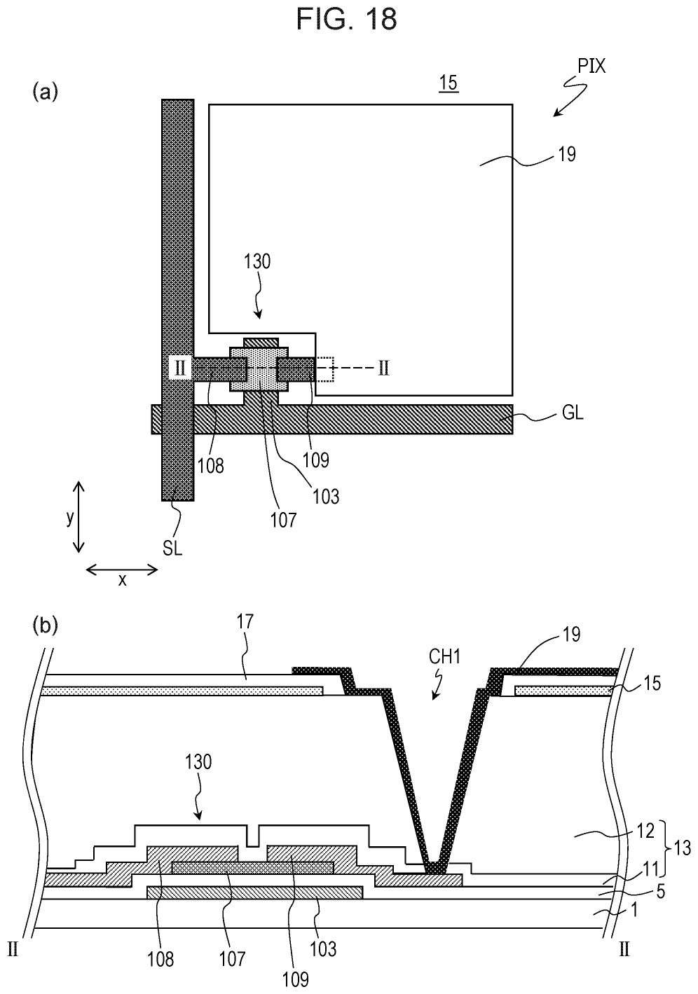

In the active matrix substrate applied to a display device that operates in the transverse electric field mode, a lower transparent electrode, and an upper transparent electrode are disposed on the display area via a dielectric layer (see FIG. 18). One of the lower transparent electrode and the upper transparent electrode is a pixel electrode PE, and the other is a common electrode CE. In this case, the upper gate electrode 14 can be formed using the same transparent conductive film as the lower transparent electrode or the upper transparent electrode. When the upper gate electrode 14 is formed using the same transparent conductive film as the lower transparent electrode, the inorganic insulation layer 11 which is a passivation film can function as a gate insulation film. When the upper gate electrode 14 is formed using the same transparent conductive film as the upper transparent electrode, the inorganic insulation layer 11 and the dielectric layer can function as the gate insulation film.

The lower gate electrode 3 may have a first edge portion 3e1 and a second edge portion 3e2 facing each other when viewed in the direction normal to the substrate 1, and the first edge portion 3e1 and the second edge portion 3e2 may generally extend in the channel width direction DW. The lower gate electrode 3 may be a part of the control signal branch line C extending in the channel width direction DW. Further, the oxide semiconductor layer 7 may be located inside the edge portion of the lower gate electrode 3 when viewed in the direction normal to the substrate 1.

When viewed in the direction normal to the substrate 1, the source electrode 8 may extend across the oxide semiconductor layer 7 in the channel width direction DW. As illustrated in the drawing, edge portions 8e1 and 8e2 of the source electrode 8 facing each other may be located on the oxide semiconductor layer 7. Similarly, the drain electrode 9 may extend across the oxide semiconductor layer 7 in the channel width direction DW. Edge portions 9e1 and 9e2 of the drain electrode 9 facing each other may be located on the oxide semiconductor layer 7.

When viewed in the direction normal to the substrate 1, the upper gate electrode 14 has two edge portions 14e1 and 14e2 that face each other and extend in the channel width direction DW. The edge portions 14e1 and 14e2 may generally extend across the oxide semiconductor layer 7 in the channel width direction DW. Further, the source electrode 8 may overlap with the edge portion 14e1, and the drain electrode 9 may overlap with the edge portion 14e2. In this way, the overlapping area of the upper gate electrode 14 and the source electrode 8, and the drain electrode 9 can be reduced.

### About the Effect of this Present Embodiment

Hereinafter, the effect obtained by using the TFT having the back gate electrode as the DMX circuit TFT and connecting the back gate electrode to the V terminal will be described using experimental results.

### (i) Effect of Back Gate in Single TFT

The inventor first examined the effect of providing a back gate in a TFT.

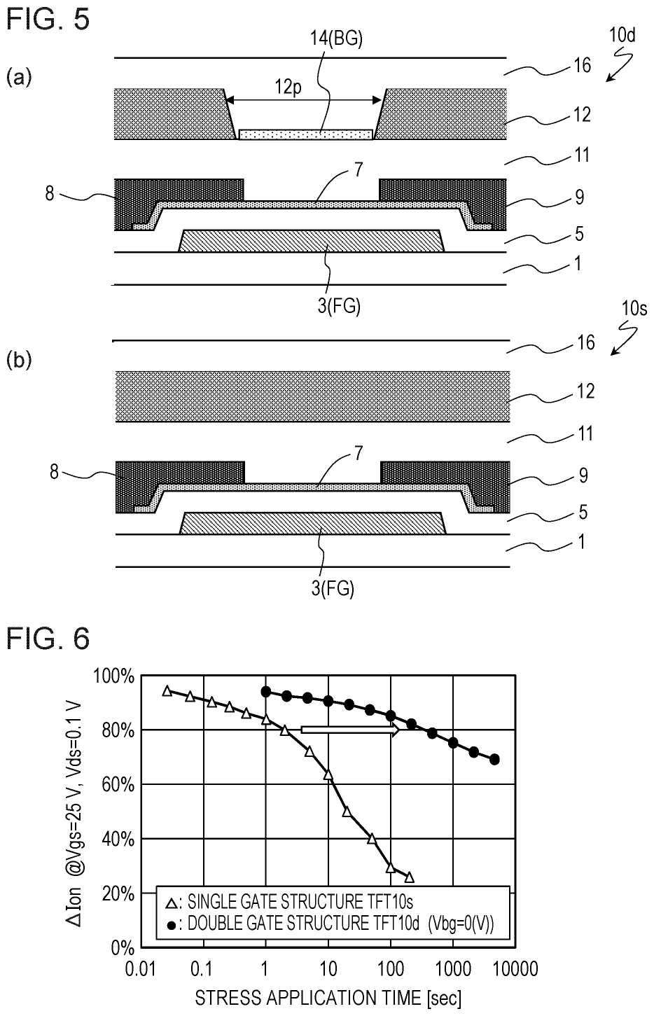

Here, as the evaluation TFT, a double gate structure TFT 10d having a back gate and a single gate structure TFT 10s having no back gate were produced. FIGS. 5(a) and 5(b) are sectional diagrams that illustrate the double gate structure TFT 10d and the single gate structure TFT 10s, respectively. In FIG. 5, the same components as those in FIG. 4 are denoted by the same reference signs. In any TFT, the channel length L is 6 μm and the channel width W is 10 μm.

The double gate structure TFT 10d has the configuration described above with reference to FIG. 4. However, the organic insulation layer 12 is provided as a planarizing film on the inorganic insulation layer 11. An opening 12p reaching the inorganic insulation layer 11 is formed in the organic insulation layer 12. The upper gate electrode 14 is provided in the opening 12p and is disposed to be in contact with the inorganic insulation layer 11 in the opening 12p. An upper insulation layer 16 is provided on the organic insulation layer 12 and the upper gate electrode 14. It is noted that the lower gate electrode 3 is the front gate electrode FG, and the upper gate electrode 14 is the back gate electrode BG.

The single gate structure TFT 10s is covered with the inorganic insulation layer 11 and the organic insulation layer 12 and is different from the double gate structure TFT 10d in that it does not have the upper gate electrode 14.

In the double gate structure TFT 10d, the back gate potential (back gate-source potential) Vbg is fixed to 0V (Vbg=0V) by electrically connecting the upper gate electrode 14 that is the back gate electrode BG to the source electrode 8. In this state, 35 V stress (Vds stress) is applied between the drain and source, and the relationship between the Vds stress application time and the on-current is examined. The on-current is measured with a gate voltage (front gate-source voltage) Vgs of 25V and a drain voltage (drain-source voltage) Vds of 0.1V. For comparison, the same Vds stress is also applied to the single gate structure TFT 10s, and the relationship between the Vds stress application time and the on-current is examined.

FIG. 6 is a diagram illustrating a relationship between a Vds stress application time and an on current in the double gate structure TFT 10d and the single gate structure TFT 10s. The horizontal axis represents the Vds stress application time (seconds), and the vertical axis represents the ratio ΔIon (%) of the on-current after applying the Vds stress to the initial on-current of each TFT before applying the Vds stress.

From the measurement results shown in FIG. 6, it can be seen that in the single gate structure TFT 10s, the on-current is greatly reduced due to the Vds stress, and the deterioration occurs. On the other hand, in the double gate structure TFT 10d, the reduction in the on-current due to the Vds stress is greatly suppressed as compared with the single gate structure TFT 10s. When the stress application time when the ratio ΔIon to the initial on-current is 80% is compared, the breakdown voltage is improved by about two digits. Therefore, it is found that the breakdown voltage against the Vds stress of the TFT can be improved by stabilizing the potential Vbg of the back gate.

Next, in the double gate structure TFT 10d, the change in the Vg-Id characteristics (initial characteristics) was examined by changing the back gate potential Vbg. Here, a voltage of 20V was applied between the source and the drain (Vds=20V), and the drain current Id when the back gate potential Vbg was −4V, −2V, 0V, 2V, 4V was measured.

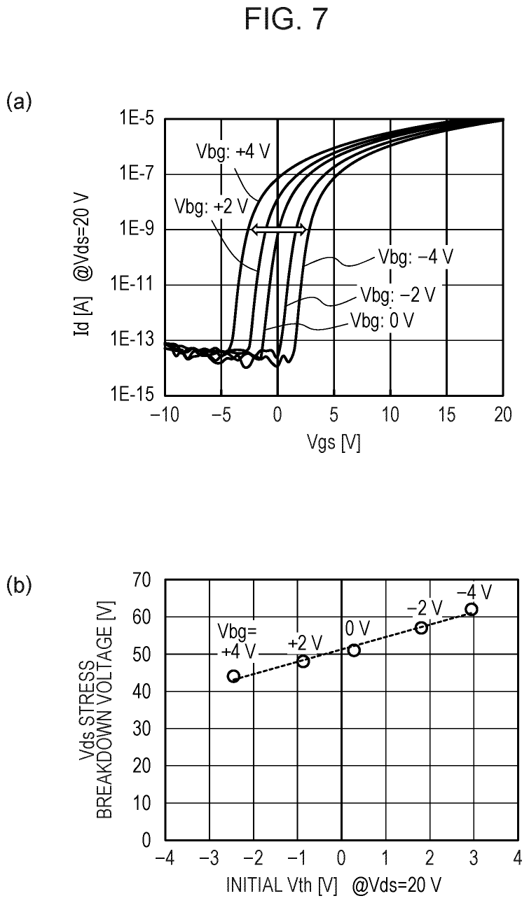

FIG. 7(a) is a graph illustrating dependency of Vg-Id characteristics on the back gate potential Vbg. The horizontal axis represents the gate voltage Vgs, and the vertical axis represents the drain current Id. From this result, it can be seen that the threshold voltage Vth can be controlled by controlling the back gate potential Vbg. It can be seen that the threshold voltage Vth decreases as the back gate potential Vbg is increased in the positive direction, and the on-current can be increased with the same gate voltage Vgs.

Subsequently, the breakdown voltage against Vds stress was examined by changing the back gate potential Vbg.

FIG. 7(b) is a graph illustrating dependency of Vds stress breakdown voltage on the back gate potential Vbg. The horizontal axis represents the initial threshold voltage Vth (see FIG. 7(a)) when Vd=20V, and the vertical axis represents the Vds stress breakdown voltage. From this result, it can be seen that the breakdown voltage decreases as the back gate potential Vbg is increased in the positive direction.

Therefore, it is confirmed that, when the back gate potential Vbg is increased (increased in the positive direction), the Vds stress breakdown voltage decreases, but the on-current increases, and when the back gate potential Vbg is decreased (increased in the negative direction), the on-current decreases, but the Vds stress breakdown voltage is increased.

### (ii) Effect of Connecting Back Gate to V Terminal

A circuit in which the back gate of the double gate structure TFT is connected to the V terminal was manufactured as the demultiplexer circuit of Example, and a circuit in which the back gate of the double gate structure TFT is grounded was manufactured as the demultiplexer circuit of Comparative Example.

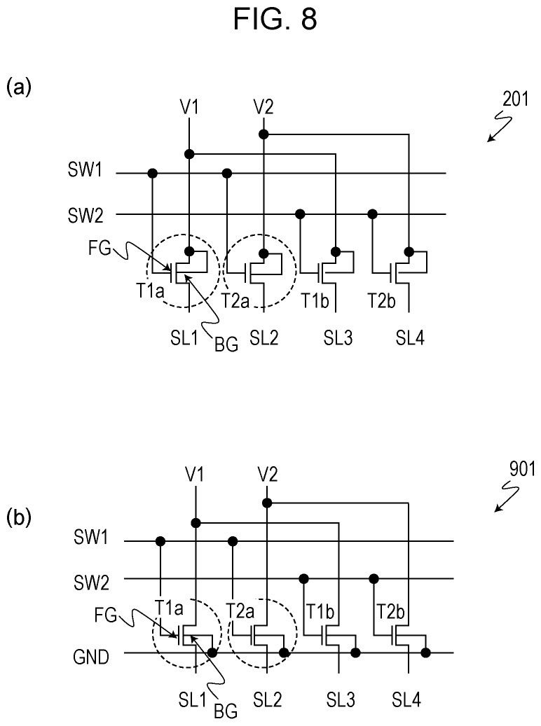

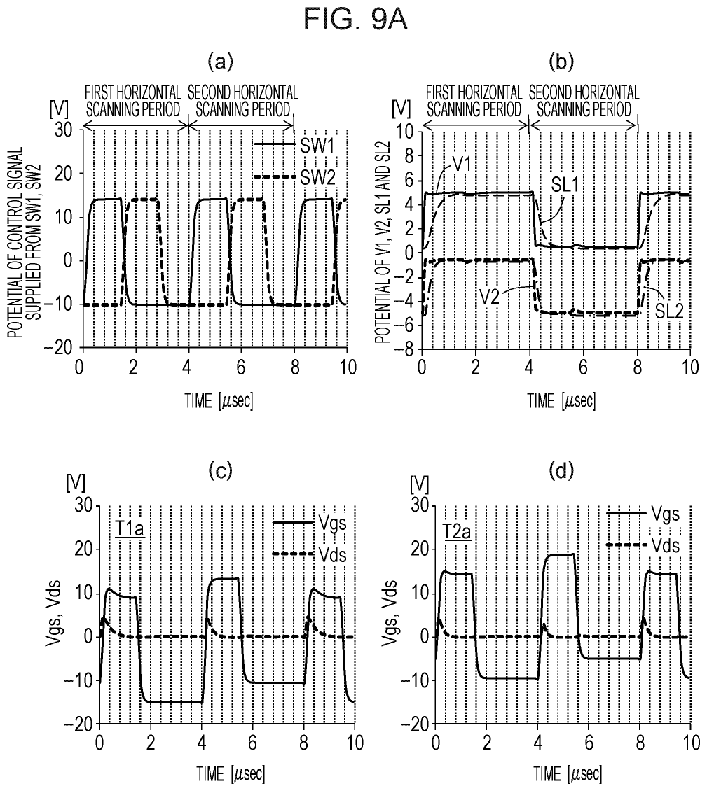

FIGS. 8(a) and 8(b) are diagrams that illustrate one sub circuit 201 and one sub circuit 901 in demultiplexer circuits of Example and Comparative Example, respectively. The same components as the sub circuit 200 in FIG. 3 are denoted by the same reference signs.

In the sub circuit 201 of Example, back gate electrodes BG of thin-film transistors T1a, T1b, T2a and T2b are electrically connected to the V terminal. The sub circuit 201 of Example has substantially the same configuration of that of the sub circuit 200 shown in FIG. 3. In Comparative Example, back gate electrodes BG of thin-film transistors T1a, T1b, T2a and T2b are fixed to the GND potential (grounded).

Here, in the following two cases as examples, The waveforms of the back gate potentials Vbg of the thin-film transistors T1a and T2a in the sub circuits 201 and 901 of Example and Comparative Example were examined.

[Case 1] A video signal V1 is input to source bus lines SL such that, in the first horizontal scanning (1H) period, the potentials of the source bus lines SL1 and SL3 are set to be sequentially increased (here, the potential to display the highest gradation), and in the second horizontal scanning period, the potentials of the source bus lines SL1 and SL3 are set to be sequentially decreased (here, the potential to display the lowest gradation). At the same time, a video signal V2 is input to the source bus line SL such that in the first horizontal scanning (1H) period, the potentials of the source bus lines SL2 and SL4 are set to be sequentially increased and in the second horizontal scanning period, the potentials of the source bus lines SL2 and SL4 are set to be sequentially decreased.

[Case 2] The video signal V1 is input to source bus lines SL such that, in the first horizontal scanning period, the potential of the source bus line SL1 is set to a high potential (here, the potential to display the highest gradation) and the potential of the source bus line SL3 is set to a low potential (here, the potential to display the lowest gradation), and in the second horizontal scanning period, the potential of the source bus line SL1 is set to the low potential and the potential of SL3 is set to the high potential. The video signal V2 is input to source bus lines SL such that, in the first horizontal scanning period, the potential of the source bus line SL2 is set to a high potential and the potential of the source bus line SL4 is set to a low potential, and in the second horizontal scanning period, the potential of the source bus line SL2 is set to the low potential and the potential of SL4 is set to the high potential.

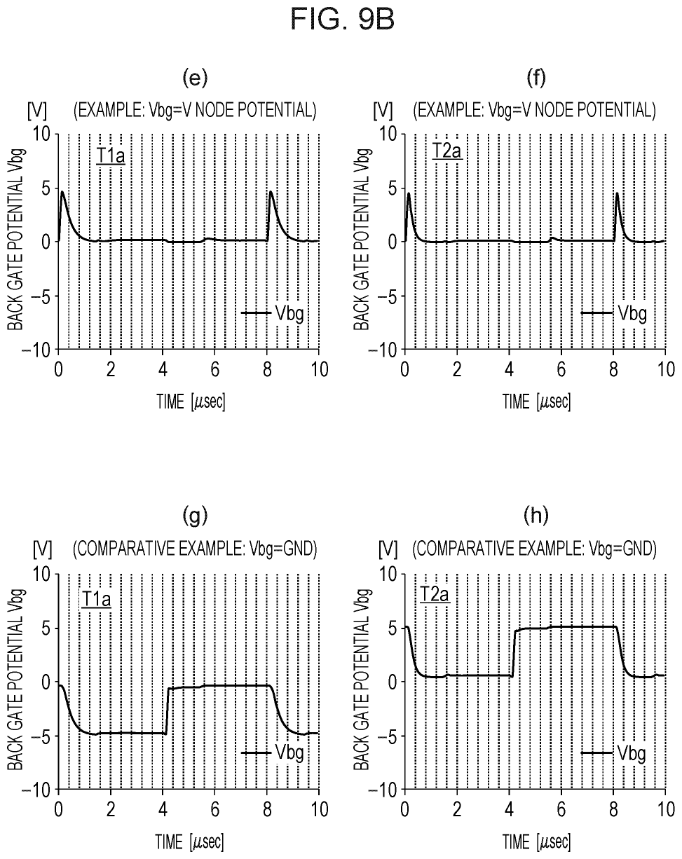

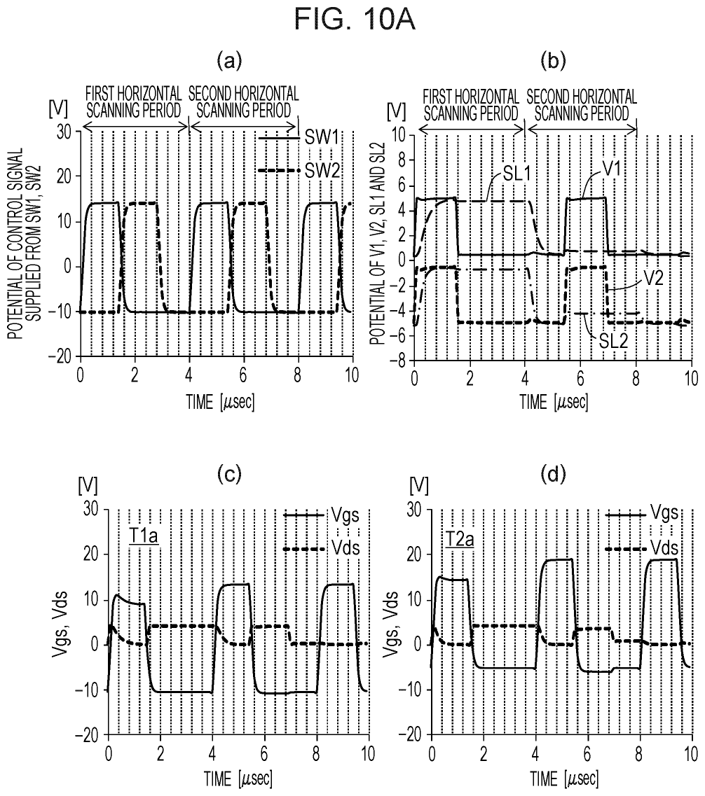

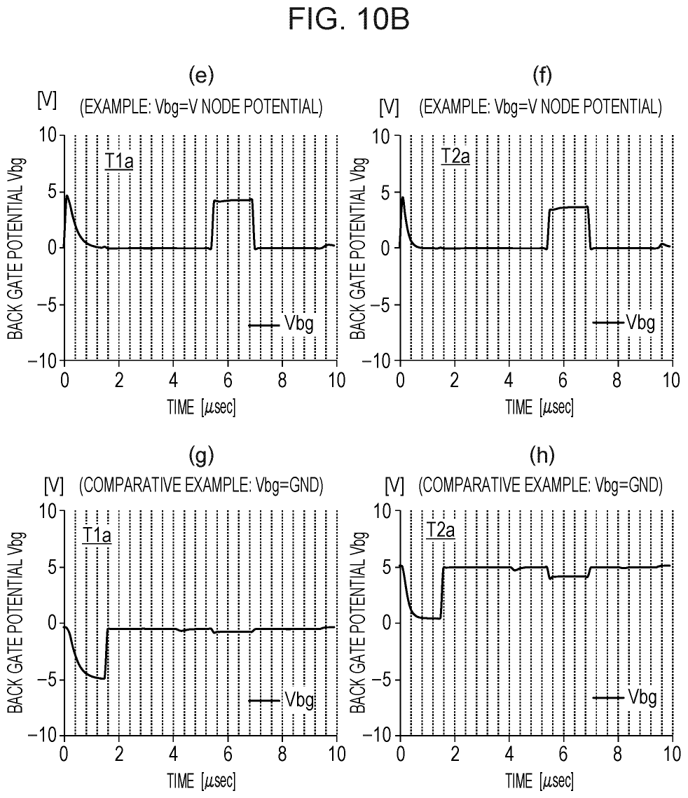

FIGS. 9A and 9B are diagrams illustrating waveforms of respective signals or voltages in Case 1. FIGS. 10A and 10B are diagrams illustrating waveforms of respective signals or voltages in Case 2. FIG. 9A(a) and FIG. 10A(a) are diagrams illustrating signal waveforms of control signals supplied from the control signal trunk lines SW1 and SW2. FIG. 9A(b) and FIG. 10A(b) are diagrams illustrating signal waveforms of the video signals V1 and V2 and potential waveforms of the source bus lines SL1 and SL2. FIGS. 9A(c) and 9A(d), and FIGS. 10A(c) and 10A(d) are diagrams illustrating gate-source voltages Vgs and drain-source voltage Vds of the thin-film transistors T1a and T2a, respectively. FIGS. 9B(e) and 9B(f) and FIGS. 10B(e) and 10B(f) are diagrams illustrating back gate potentials Vbg of the thin-film transistors T1a and T2a in the sub circuit 201 of Example, respectively. FIGS. 9B(g) and 9B(h) and FIGS. 10B(g) and 10B(h) are diagrams illustrating back gate potentials Vbg of the thin-film transistors T1a and T2a in the sub circuit 901 of Comparative Example, respectively.

As can be seen from FIGS. 9B(g) and 9B(h) and FIGS. 10B(g) and 10B(h), in Comparative Example, the back gate potential Vbg changes within the range of −5V to +5V depending on the write condition. As exemplified in the first horizontal scanning period illustrated in FIG. 9B(g), when a large negative voltage (−5V) is applied to the back gate, the driving force of the TFT may be reduced. Further, as exemplified in FIG. 9B(h) and FIG. 10B(h), when a positive bias (+5V) is applied to the back gate for a long period, device characteristics may be deteriorated due to stress.

On the other hand, as can be seen from FIGS. 9B(e) and 9B(f) and FIGS. 10B(e) and 10B(f), in the embodiment, the back gate potential Vbg is normally fixed to 0V. Since the back gate potential Vbg can be stabilized (Vbg=0V), the breakdown voltage can be improved (see FIG. 6).

When the potentials of the source bus lines SL1 and SL2 connected to the thin-film transistors T1a and T2a are set to be sequentially increased (for example, 0V to +5V) (referred to as “worst case”), a positive bias of 5V is applied to the back gates the thin-film transistors T1a and T2a. As a result, the threshold voltages of the thin-film transistors T1a and T2a are effectively lowered, and thus the driving force can be increased (see FIG. 7(a)). Therefore, it is advantageous since the driving force can be increased without increasing the size (channel width) of the TFT.

In the embodiment, in the worst case, the back gate potential Vbg becomes +5V at the initial stage of charging of the source bus lines SL1 and SL2, but as the charging proceeds, the back gate potential Vbg approaches 0V. Therefore, the time for applying the positive bias to the back gate is extremely short. For example, in the second horizontal scanning period illustrated in FIGS. 10B(e) and 10B(f), after the potential of the first source bus line SL1 is fixed to 0V, a positive bias of +5V is applied to the back gate even when =5V is input to the third source bus line SL3. However, the application time is only the period during which the source bus line SL3 is charged (period t7 in FIG. 3(b)). As described above, since +5V is not applied to the back gate potential Vbg for a long time, it is possible to suppress degradation of TFT characteristics due to Vbg stress.

Further, in the embodiment, since the back gate potential Vbg is 0 V or more, it is possible to suppress a decrease in driving force of the thin-film transistors Tia and T2a due to a large negative voltage applied to the back gate.

As can be seen from the result, when the back gate of the TFT is connected to the V terminal, the reliability of the TFT is improved as compared with when the back gate of the TFT is connected to the GND, and only when write is performed under a prescribed condition, the current driving force can be increased by setting the back gate potential Vbg to High.

### Layout Example of Demultiplexer Circuit DMX_A

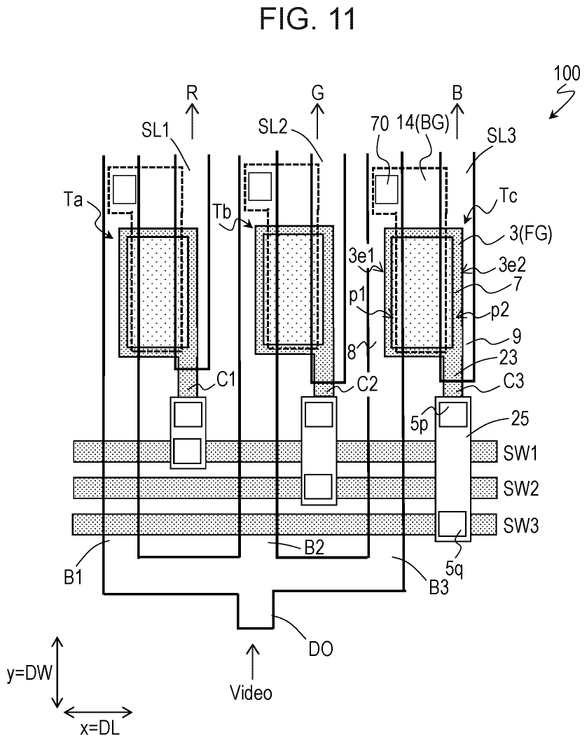

FIG. 11 is a plan view illustrating the unit circuit 100 in the demultiplexer circuit DMX_A. The unit circuit 100 has the configuration described above with reference to FIG. 2. In the example, in the unit circuit 100, source bus lines SL(1) to SL(3) associated with R, G, and B pixels are disposed (that is, n=3).

The unit circuit 100 includes three thin-film transistors Ta to Tc (DMX circuit TFT) that are supported on the substrate 1, source bus lines SL1 to SL3 (hereinafter collectively referred to as “source bus line SL”) that extend from the display area DR, one video signal line DO, branch wiring lines B1 to B3 (hereinafter, in some cases, collectively referred to as “branch wiring line B”), and control signal trunk lines SW1 to SW3 (hereinafter, in some case, collectively referred to as “control signal trunk line SW”). The video signal line DO is electrically connected to the branch wiring lines B1 to B3. In the example, the source bus line SL extends in the y direction, and the control signal trunk line SW extends in the x direction intersecting the y direction. The branch wiring line B and the video signal line DO are formed in the source metal layer. The lower gate electrode 3 and the control signal line SW are formed in the gate metal layer. The upper gate electrode 14 extends in the y direction and is connected to the branch wiring line B at the contact portion 70.

In the present embodiment, the thin-film transistors Ta to Tc are respectively disposed between two adjacent source bus lines SL (overlapping one source bus line). In the example, the channel length direction DL of each of the thin-film transistors Ta to Tc is approximately parallel to the x direction and the channel width direction DW thereof is approximately parallel to the y direction.

The source bus lines SL may extend in the y direction from the display area to the source driver SD and may be in contact with the upper surface of one end p2 of the corresponding oxide semiconductor layer 7 extending in the channel width direction DW. The portion of the source bus line SL that is in contact with the oxide semiconductor layer 7 functions as the drain electrode 9 of the DMX circuit TFT.

Each branch wiring line B extends in the y direction from the video signal line DO to the display area, and is in contact with the upper surface of the other end p1 of the corresponding oxide semiconductor layer 7 extending in the channel width direction DW. The portion of the branch wiring line B in contact with the oxide semiconductor layer 7 functions as the source electrode 8 of the DMX circuit TFT.

The lower gate electrode 3 of each of the thin-film transistors Ta to Tc is electrically connected to the corresponding control signal trunk line SW via the control signal branch line C. In the example, the control signal branch line C includes an extended portion (extension portion) 23 of the lower gate electrode 3 and a connection wiring line 25 formed in the source metal layer. The extension portion 23 extends in the y direction toward the control signal trunk line SW, and is electrically connected to the corresponding control signal trunk line SW via the connection wiring line 25. The connection wiring lines 25 may be, for example, in contact with the extension portion 23 in a first opening 5p provided in the gate insulation layer 5 and may be in contact with the control signal trunk line SW in a second opening 5q provided in the gate insulation layer 5.

The thin-film transistors Ta to Tc and the demultiplexer circuit DMX may be covered with an inorganic insulation layer (passivation film) 11 (see FIG. 4). A planarization film such as an organic insulation layer 12 (See FIG. 5) may or may not be provided on the inorganic insulation layer 11. For example, the display area DR of the active matrix substrate 1000 may be covered with the organic insulation layer 12, and the non-display area FR may not be covered with the organic insulation layer 12. An organic insulation layer 12 is provided so as to cover the demultiplexer circuit DMX, and the organic insulation layer 12 may have openings in portions positioned on the thin-film transistors Ta to Tc (see FIG. 5(a)).

### Layout Example of Demultiplexer Circuit DMX_B

Then, a layout example of the demultiplexer circuit DMX_B described above will be described with reference to FIG. 3. Hereinafter, differences from the above-described demultiplexer circuit DMX_A will be mainly described, and description of similar configurations will be omitted.

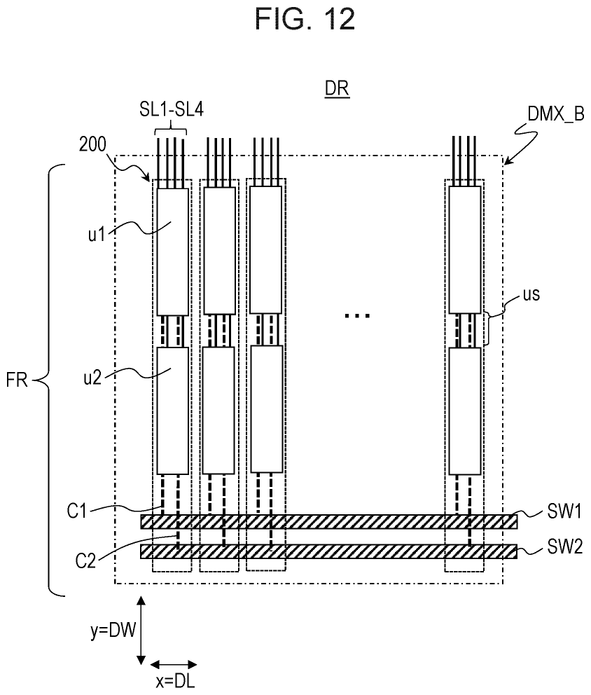

FIG. 12 is a plan view illustrating one example of a layout of the demultiplexer circuit DMX_B.

The demultiplexer circuit DMX_B is disposed below the display area DR when viewed in the direction normal to the substrate 1. In the example, the demultiplexer circuit DMX_B has a plurality of sub circuits 200 arranged in the x direction. Each of the sub circuits 200 has a shape extending in the y direction.

When each sub circuit 200 is viewed in the direction normal to the substrate 1, a first unit circuit formation area u1 in which the DMX circuit TFT of the first unit circuit is positioned on the side of the display area of a second unit circuit formation area u2 in which the DMX circuit TFT of the second unit circuit is disposed. That is, the first unit circuit is positioned between the second unit circuit and the display area. In the specification, such a configuration is referred to as a “two-stage configuration”.

n (here, two) control signal trunk lines SW1 and SW2 are arranged between the demultiplexer circuit DMX_B and the edge portion of the non-display area FR. The control signal branch lines C1 and C2 of each sub circuit 200 extend from the control signal trunk lines SW1 and SW2 into the demultiplexer circuit DMX_B, respectively. Although not illustrated, between the demultiplexer circuit DMX_B and the edge portion of the non-display area FR, a drive circuit and video signal lines that ae COG mounted also provided. The branch wiring lines B1a, B2a, B1b, and B2b of each sub circuit 200 extend from the video signal line into the demultiplexer circuit DMX_B, respectively.

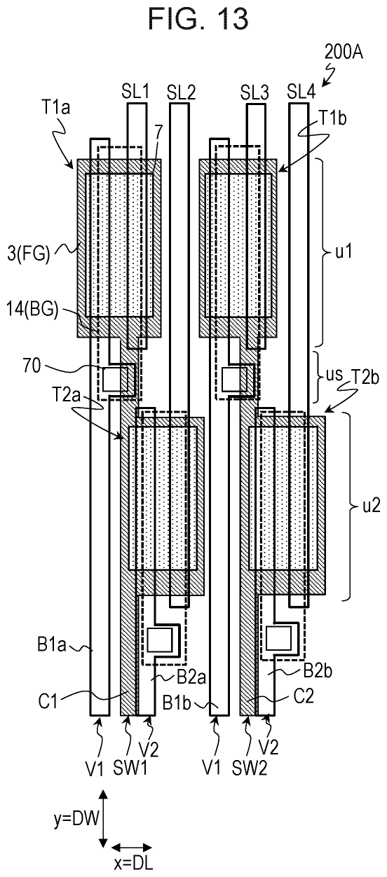

FIG. 13 is an enlarged plan view illustrating one sub circuit 200A in the demultiplexer circuit DMX_B.

In the sub circuit 200A, the branch wiring lines B1a, B2a, B1b, B2b, the control signal branch lines C1, C2 and the source bus lines SL1 to SL4 of the first unit circuit and the second unit circuit all extend in the y direction.

The control signal branch lines C1 and C2 each include a portion that functions as a gate electrode of the corresponding DMX circuit TFT. For example, the control signal branch line C1 is positioned between the branch wiring line B1a and the branch wiring line B2a when viewed from in the direction normal to the substrate 1. The control signal branch line C1 has a protrusion that protrudes in the x direction on the side of the branch wiring line B2a and functions as a gate electrode of the thin-film transistor T2a, and a protrusion that protrudes in the x direction on the side of the branch wiring line B2a and functions as a gate electrode of the thin-film transistor T1a. The oxide semiconductor layers 7 of the thin-film transistors T1a and T2a are disposed on the protrusions of the control signal branch line C1, respectively. As described above, one of the DMX circuit TFTs in the first unit circuit and one of the DMX circuit TFTs in the second unit circuit have gate electrodes formed integrally on the same control signal branch line C, and are arranged on the same control signal branch line C with an interval (two-stage configuration).

The source bus lines SL1 to SL4 are in contact with the oxide semiconductor layers 7 of corresponding DMX circuit TFTs, respectively, and include portions that function as the drain electrodes. For example, the first source bus line SL1 extends in the y direction from the display area DR and is in contact with the upper surface of the oxide semiconductor layer 7 of the thin-film transistor T1a. The second source bus line SL2 extends in the y direction from the display area DR between the thin-film transistors T1a and T1b, and is in contact with the upper surface of the oxide semiconductor layer 7 of the thin-film transistor T2a.

The branch wiring lines B1a, B2a, B1b, and B2b are in contact with the oxide semiconductor layers 7 of corresponding DMX circuit TFTs, respectively, and include portions that function as the source electrodes. For example, the branch wiring line B2a extends in the y direction from the COG side and is in contact with the upper surface of the oxide semiconductor layer 7 of the thin-film transistor T2a. The branch wiring line B1b extends in the y direction from the COG side between the thin-film transistors T2a and T2b, and is in contact with the upper surface of the oxide semiconductor layer 7 of the thin-film transistor T1b.

The upper gate electrode 14 of each thin-film transistor is connected to the video signal line DO (or V terminal) via the branch wiring line B (that is, V terminal). The upper gate electrode 14 may extend in the y direction on the control signal branch line C.

The contact portion 70 connecting the upper gate electrode 14 to the branch wiring line B may be disposed in an area us (hereinafter referred to as “connection area”) positioned between a first unit circuit formation area u1 and a second unit circuit formation area u2. In this way, an increase in the circuit area of the demultiplexer circuit DMX can be suppressed. In the contact portion 70, the upper gate electrode 14 may be in direct contact with the branch wiring line B in the opening formed in the inorganic insulation layer 11. Here, the contact portion 70 connecting the upper gate electrodes 14 and the branch wiring lines B in the thin-film transistors T1a and T1b of the first unit circuit are disposed in the connection area us. In addition, the contact portion 70 connecting the upper gate electrodes 14 and the branch wiring lines B in the thin-film transistors T2a and T2b of the second unit circuit are disposed between the second unit circuit formation area u2 and the control signal trunk line SW. Contact portions connecting the upper gate electrodes 14 and the branch wiring lines B in the thin-film transistors T2a and T2b of the second unit circuit may be disposed in the connection area us, and contact portions connecting the upper gate electrodes 14 and the branch wiring lines B in the thin-film transistors T1a and T1b of the first unit circuit may be disposed between the first unit circuit formation area u1 and the display area DR.

When viewed in the direction normal to the substrate 1, the DMX circuit TFT of the first unit circuit is disposed between the Nth and (N+2)th source bus lines SL associated with the second unit circuit. (N is a natural number). For example, the thin-film transistor T1b is disposed between the second source bus line SL2 and the fourth source bus line SL4. The DMX circuit TFT of the second unit circuit is disposed between two adjacent branch wiring lines B in the first unit circuit. For example, the thin-film transistor T2a is disposed between the branch wiring lines B1a and B2a of the first unit circuit.

In the present embodiment, the drain electrode of each DMX circuit TFT is a part of the source bus line SL, the source electrode is a part of the branch wiring line B, and the gate electrode is a part of the control signal branch line C. Further, a common control signal branch line C is provided for two or more unit circuits. In this way, the area required for the demultiplexer circuit DMX can be more effectively reduced. Further, the current driving force can be further increased by increasing the channel width W in the y direction.

Further, in the present embodiment, since the plurality of unit circuits are arranged in a two-stage configuration, a DMX circuit TFT having a desired size can be formed even if the arrangement pitch of the source bus lines SL is narrowed. For example, in the embodiment described above, it is necessary to dispose the DMX circuit TFTs between two adjacent source bus lines SL. In contrast, in the present embodiment, for example, since the DMX circuit TFT may be disposed between the Nth source bus line SL and the (N+2)th source bus line SL, a highly reliable DMX circuit TFT having the desired channel length and overlapping length can be formed. Therefore, the present embodiment can be suitably applied to an ultra-high definition active matrix substrate exceeding 1000 ppi, for example. By forming the demultiplexer circuit DMX using an oxide semiconductor monolithically, the area of the wiring/terminal region in the non-display area can be reduced, and thus a frame-narrowing can be achieved.

Here, an example of a two-stage configuration is illustrated, but a configuration of three or more stages can also be employed. Even in this case, similarly to above, each sub circuit may include three or more unit circuits, and the DMX circuit TFTs of the unit circuits may be arranged on the common control signal branch line with an interval.

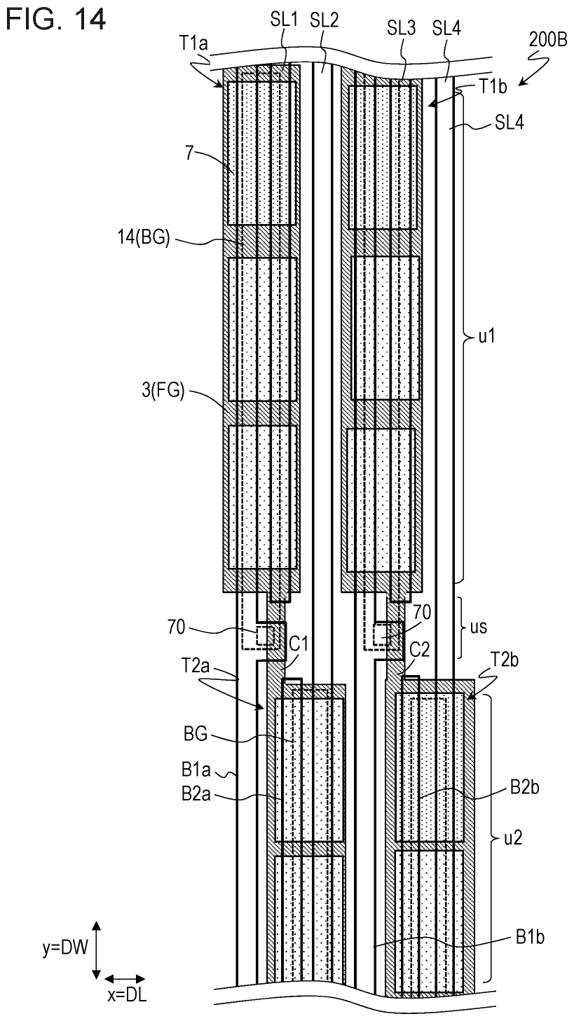

FIG. 14 is a plan view illustrating a part of another sub circuit 200B the demultiplexer circuit DMX_B.

The sub circuit 200B is different from the sub circuit 200A illustrated in FIG. 13 in that a plurality of thin-film transistors connected in parallel are provided for one source bus line SL.

In the example, a plurality of thin-film transistors T1a connected in parallel to each other is connected to the first source bus line SL1, for example. The thin-film transistors T1a are arranged in the y direction on the control signal branch line C1, and have a part of the control signal branch line C1 as a gate electrode and a part of the branch wiring line B1a as a source electrode, and a part of the first source bus line SL1 as a drain electrode. Similarly, a plurality of thin-film transistors T2a, T1b, and T2b connected in parallel to each other are connected to other source bus line SL1 to SL4. With such a configuration, the current driving force can be further increased while suppressing an increase in circuit area.

In the sub circuit 200B, the common upper gate electrode 14 is provided for a plurality of thin-film transistors arranged in the y direction. The common upper gate electrode 14 may extend in the y direction. Each common upper gate electrode 14 is connected to the video signal line DO (or V terminal) via the branch wiring line B (that is, V terminal).

The sub circuit 200B is provided with a plurality of contact portions 70. The contact portions 70 connect the common upper gate electrode 14 to the corresponding branch wiring lines B. The arrangement of the contact portions 70 may be the same as that of the sub circuit 200A. That is, some of a plurality of contact portions 70 may be disposed in the connection area us positioned between the first unit circuit formation area u1 and the second unit circuit formation area u2.

The number of TFTs connected in parallel is not particularly limited, but can be set as appropriate such that the total channel width W of the TFTs becomes a prescribed value W_{Total}. However, the channel width W of each TFT (the length of the oxide semiconductor layer 7 in the channel width direction DW) is preferably 6 μm or more and 100 μm or less, for example. If the channel width W is 6 μm or less, desired characteristics may not be obtained. If the channel width W is larger than 100 μm, the TFT characteristics may not be stable. For example, when W_{Total} is 300 μm, three or more TFTs with W 100 μm may be connected in parallel. If W_{Total} is 100 μm or less, one TFT having a large channel width W (W=W_{Total}) may be formed instead of connecting a plurality of TFTs in parallel.

### Other Variations

In the above, the demultiplexer circuit DMX_B in which each unit circuit is associated with two source bus lines (n=2) has been described as an example. However, the unit circuit of the demultiplexer circuit of the present embodiment may have three or more source bus lines.

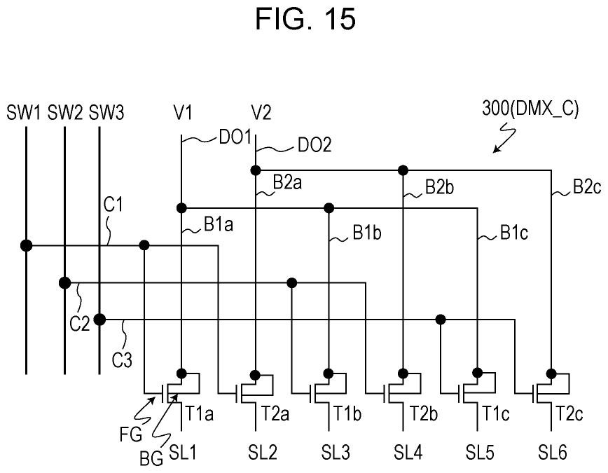

FIG. 15 is a view illustrating a configuration of a sub circuit 300 in another demultiplexer circuit DMX_C according to the present embodiment.

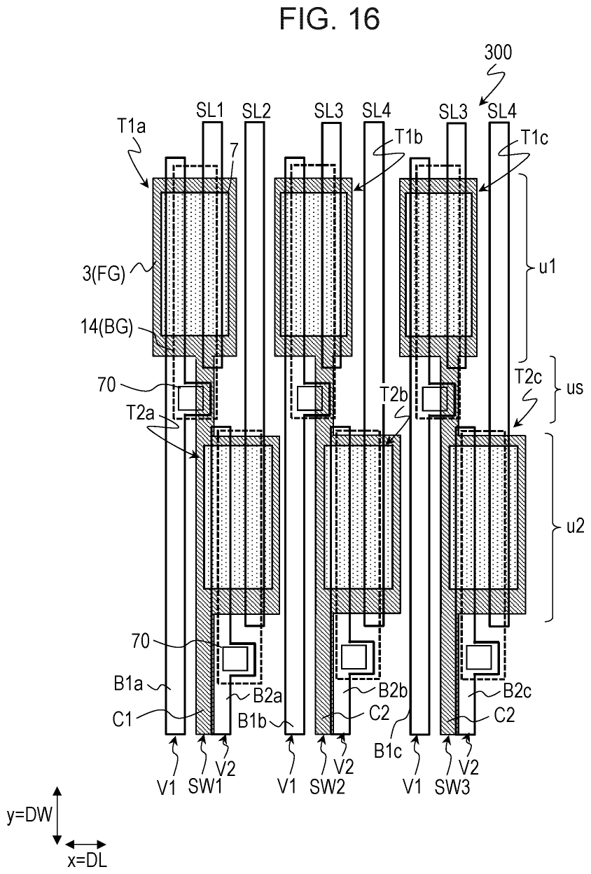

The sub circuit 300 includes a first unit circuit and a second unit circuit, similar to the sub circuit 200 described above. However, the sub circuit 300 is different from the sub circuit 200 illustrated in FIG. 16 in that each unit circuit distributes the video signal V1 from the video signal line DO (N) to three source bus lines SL arranged every other line.

The first unit circuit is associated with the first, third, and fifth source bus lines SL1, SL3, SL5 arranged every other line, and the second unit circuit is associated with the second, fourth, and sixth source bus lines SL2, SL4, and SL6 arranged every other line. In addition, the first unit circuit and the second unit circuit use common control signal branch lines C1, C2 and C3.

The first unit circuit includes three thin-film transistors (DMX circuit TFTs) T1a, T1b and Tc, and three branch wiring lines B1a, B1b and B1c. The second unit circuit includes three thin-film transistors (DMX circuit TFTs) T2a, T2b and T2c, and three branch wiring lines B2a, B2b and B2c. The branch wiring lines B1a, B1b and B1c of the first unit circuit are electrically connected to the video signal line DO1, and the branch wiring lines B2a, B2b and B2c of the second unit circuit are electrically connected to the video signal line DO2. The drain electrodes of the thin-film transistors T1a, T1b and T1c of the first unit circuit are connected to the first source bus line SL1, the third source bus line SL3 and the fifth source bus line SL5, respectively, and the source electrodes thereof are connected to the branch wiring lines B1a, B1b and B1c, respectively. The drain electrodes of the thin-film transistors T2a, T2b and T2c of the second unit circuit are connected to the second source bus line SL2, the fourth source bus line SL4 and the sixth source bus line SL6, respectively, and the source electrodes thereof are connected to the branch wiring lines B2a, B2b and B2c, respectively. The gate electrodes of the thin-film transistors T1a and T2a are each connected to the control signal trunk line SW1 via the control signal branch line C1. The gate electrodes of the thin-film transistors T1b and T2b are each connected to the control signal trunk line SW2 via the control signal branch line C2. The gate electrodes of the thin-film transistors T1c and T2c are each connected to the control signal trunk line SW3 via the control signal branch line C3. The back gates of the thin-film transistors T1a and T1b are connected to the video signal line DO1 that supplies the input signal V1 via the branch wiring lines B1a and the branch wiring line B1b, respectively. The back gates of the thin-film transistors T2a and T2b are connected to the video signal line DO2 that supplies the input signal V2 via the branch wiring lines B2a and the branch wiring line B2b, respectively.

FIG. 16 is an enlarged plan view illustrating an example of the sub circuit 300. Also in the sub circuit 300, similarly to the sub circuits 200A and 200B described above, the first unit circuit formation area u1 in which the thin-film transistors T1a, T1b, and T1c of the first unit circuit are arranged is located closer to the display area than the second unit circuit formation area u2 in which the thin-film transistors T2a, T2b and T2c of the second unit circuit are arranged. The thin-film transistor of the first unit circuit is disposed between the Nth and (N+2)th source bus lines SL associated with the second unit circuit. For example, the thin-film transistor T1b is disposed between the second source bus line SL2 and the fourth source bus line SL4, and the thin-film transistor T1c is disposed between the fourth source bus line SL4 and the sixth source bus line SL6. The thin-film transistor of the second unit circuit is disposed between the branch wiring lines B of the first unit circuit. For example, the thin-film transistor T2a is disposed between the branch wiring line B1a and the branch wiring line B1b, and the thin-film transistor T2b is disposed between the branch wiring line B1b and the branch wiring line B1c.

### Phase Development of Control Signal

The control signal supplied by the control signal trunk line SW may be phase-developed. Although the demultiplexer circuit DMX described above has n control signal trunk lines SW, K×n (K is an integer of 2 or more) control signal trunk lines SW may be provided.

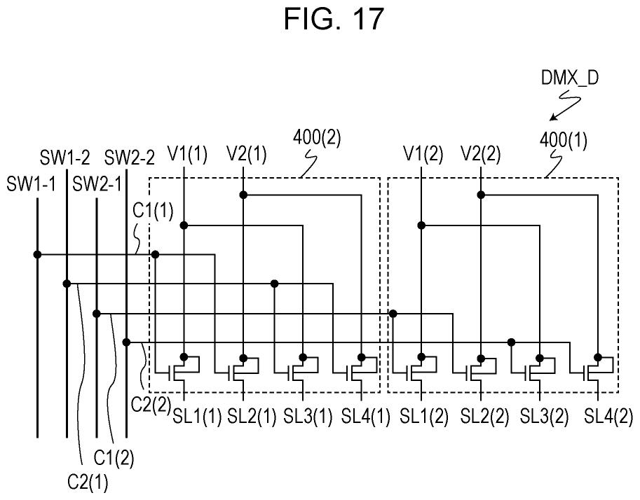

FIG. 17 is a diagram illustrating configurations of two sub circuits 400(1) and 400(2) in a demultiplexer circuit DMX_D that phase-develops the control signal. Each unit circuit is associated with two source bus lines SL (n=2).

The sub circuit 400(1) includes a first unit circuit and a second unit circuit, and control signal branch lines C1(1) and C2(1). The sub circuit 400(2) includes a first unit circuit and a second unit circuit, and control signal branch lines C1(2) and C2(2).

In the example, the demultiplexer circuit DMX_D has four control signal trunk lines SW1-1, SW1-2, SW2-1, and SW2-2 (K=2). The same control signal is supplied to the control signal trunk lines SW1-1 and SW1-2, and the same control signal is supplied to the control signal trunk lines SW2-1 and SW2-2. The control signal branch lines C1(1) and C2(1) of some sub circuits (including the sub circuit 400 (1)) of the demultiplexer circuit DMX_D are connected to the control signal trunk line SW1-1 and control signal trunk line SW2-1 (referred to as “first control signal trunk lines”), and the control signal branch lines C1(2) and C2(2) of other sub circuits (including the sub circuit 400 (2)) of the demultiplexer circuit DMX_D are connected to the control signal trunk line SW1-2 and the control signal trunk line SW2-2 (referred to as “second control signal trunk line”).

In this way, by performing phase development of the control signals of the control signal trunk lines SW, the number of unit circuits connected to one control signal trunk line SW can be reduced, and thus the load applied to each control signal trunk line SW can be reduced. As a result, since the transition time (rise and fall) of the control signal can be reduced, a higher speed operation is possible.

### Configuration of Pixel Area PIX

Next, a configuration of each pixel area PIX in the active matrix substrate 1000 will be described. Here, the active matrix substrate applied to an LCD panel in an FFS mode will be described as an example.

FIGS. 18(a) and 18(b) are a plan view of a pixel area PIX in the active matrix substrate 1000, and a sectional diagram taken along line IV-IV, respectively.

The pixel area PIX is an area that is surrounded with the source bus line SL that extends in the y direction, and the gate bus line GL that extends in the x direction that intersects the source bus line SL. The pixel area PIX has the substrate 1, a TFT (hereinafter, referred to as “pixel TFT”) 130 that is supported on the substrate 1, a lower transparent electrode 15 and an upper transparent electrode 19. Although not illustrated, the upper transparent electrode 19 has a slit or notch portion for each pixel. In the example, the lower transparent electrode 15 is a common electrode CE, and the upper transparent electrode 19 is a pixel electrode PE. The pixel TFT 10, for example, is an oxide semiconductor TFT that has the bottom gate structure.

Next, a structure of the pixel TFT 130 is in more detail described.

The pixel TFT 130 is a TFT having a bottom gate configuration of a gate electrode 103 that is supported in the substrate 1, the gate insulation layer 5 that covers the gate electrode 103, the oxide semiconductor layer 107 that is formed on the gate insulation layer 5, and the source electrode 108 and the drain electrode 109 that are arranged in such a manner as to be brought into contact with the oxide semiconductor layer 107 are included. Each of the source electrode 108 and the drain electrode 109 is brought into contact with an upper surface of the oxide semiconductor layer 107.

The gate electrode 103 is connected to the corresponding gate bus line GL, and the source electrode 108 is connected to the corresponding source bus line SL. The drain electrode 109 is electrically connected to the pixel electrode PE. The gate electrode 103 and the gate bus line GL may be integrally formed within the gate metal layer. The source electrode 108 and the source bus line SL may be integrally formed within the source metal layer.

An interlayer insulation layer 13 is not specifically limited. Examples of the interlayer insulation layer 13 may include the inorganic insulation layer (passivation film) 11 and the organic insulation layer 12 disposed on the inorganic insulation layer 11. The interlayer insulation layer 13 may not include the organic insulation layer 12.

The pixel electrode PE and the common electrode CE are disposed to partially overlap with each other via the dielectric layer 17. The pixel electrode PE is separated for each pixel. The common electrode CE may not be separated for each pixel. In the example, the common electrode CE may be formed on the interlayer insulation layer 13. The common electrode CE has an opening in the area where the pixel TFT 10 is formed, and may be formed over the entire pixel area PIX except for the area. The pixel electrode PE is formed on the dielectric layer 17 and is electrically connected to the drain electrode 109 in the opening CH1 provided in the interlayer insulation layer 13 and the dielectric layer 17.

This active matrix substrate 1000 can be applied to, for example, a display device in the FFS mode. The FFS mode is a lateral electric field mode in which a pair of electrodes are provided on one side of the substrate and an electric field is applied to liquid crystal molecules in a direction (lateral direction) parallel to the substrate surface. In the example, an electric field is generated, which is represented by lines of electric lines emitted from the pixel electrode PE, through a liquid crystal layer (not illustrated) and further through the slit-shaped opening of the pixel electrode PE, to the common electrode CE. The electric field has a component in the lateral direction with respect to the liquid crystal layer. As a result, it is possible to apply an electric field in the lateral direction to the liquid crystal layer. The lateral electric field method has an advantage that a wide viewing angle can be implemented as compared with the vertical electric field method because liquid crystal molecules do not rise from the substrate.

The electrode structure in which the pixel electrode PE is disposed on the common electrode CE via the dielectric layer 17 is described, for example, International Publication No. 2012/086513. The common electrode CE may be disposed on the pixel electrode PE via the dielectric layer 17. That is, the lower transparent electrode 15 formed on the lower transparent conductive layer may be pixel electrode PE, and the upper transparent electrode 19 formed on the upper transparent conductive layer may be the common electrode CE. This electrode structure is described, for example, in Japanese Unexamined Patent Application Publication Nos. 2008-032899 and 2010-008758. For reference, the entire contents of International Publication No. 2012/086513, Japanese Unexamined Patent Application Publication No. 2008-032899, and Japanese Unexamined Patent Application Publication No. 2010-008758 are incorporated herein by reference.

### Material and Thickness of Each Layer in Active Matrix Substrate 1000

The substrate 1 may be, for example, a glass substrate, a silicon substrate, a plastic substrate (resin substrate) having heat resistance, or the like.

The gate metal layer (thickness: for example, 50 nm or more and 500 nm or less) including the lower gate electrode 3 and the gate bus line GL is formed of, for example, a metal such as aluminum (Al), tungsten (W), molybdenum (Mo), tantalum (Ta), chromium (Cr), titanium (Ti), copper (Cu) or an alloy thereof, or a metal nitride thereof. Moreover, the gate metal layer may be formed of a stacked film in which multiple films of the elements are stacked. The gate metal layer can be formed by forming a metal film on the substrate 1 by sputtering or the like and patterning the metal film by a known photolithography process (photoresist application, exposure, development, etching, resist peeling). The etching is performed by, for example, wet etching.

The gate insulation layer 5 (thickness: for example, 200 nm or more and 500 nm or less) is for example, a silicon oxide (SiOx) layer, a silicon nitride (SiNx) layer, a silicon oxynitride (SiOxNy; x>y) layer, silicon nitride oxide (SiNxOy; x>y), and the like. The gate insulation layer 5 may have a stacked structure. In this case, when the SiO₂ film is disposed on the side of the gate insulation layer 5 in contact with the oxide semiconductor layer 7, it is possible to effectively reduce oxygen deficiencies in the oxide semiconductor layer 7.

The oxide semiconductor layer 7 is formed of, for example, an oxide semiconductor film (thickness: for example, 15 nm or more and 200 nm or less) such as In—Ga—Zn—O based semiconductor.

The source metal layer (thickness: for example, 50 nm or more and 500 nm or less) including the source electrode 8, the drain electrode 9 and the source bus line SL is formed using a metal such as aluminum (Al), tungsten (W), molybdenum (Mo), tantalum (Ta), chromium (Cr), titanium (Ti), copper (Cu) or an alloy thereof, or a metal nitride thereof. Moreover, the gate metal layer may be formed of a stacked film in which multiple films of the elements are stacked. The source metal layer may have a stacked structure in which a Ti film (thickness: 30 nm), an Al or Cu film (thickness: 300 nm), and a Ti film (thickness: 50 nm) are stacked in this order from the oxide semiconductor layer side.

The inorganic insulation layer 11 (thickness: for example, 100 to 500 nm, preferably 200 to 500 nm), is formed of, for example, an inorganic insulation film (passivation film) such as a silicon oxide (SiOx) film, a silicon nitride (SiNx) film, a silicon oxynitride (SiOxNy; x>y) film, a silicon nitride oxide (SiNxOy; x>y) film, and the like. The inorganic insulation layer 11 may have a stacked structure. When the SiO₂ film disposed on the side of the inorganic insulation layer 11 in contact with the oxide semiconductor layer 7, it is possible to effectively reduce oxygen deficiencies in the oxide semiconductor layer 7.

The organic insulation layer 12 (thickness: for example, 1 to 3 μm, preferably 2 to 3 μm) is formed of, for example, an organic insulation film containing a photosensitive resin material.

Each of the lower transparent electrode 15 and the upper transparent electrode 19 (thickness: for example, 50 nm or more and 200 nm or less) may be formed of, for example, an ITO (indium tin oxide) film, an In—Zn—O based oxide (indium zinc oxide) film, ZnO film (zinc oxide film), or the like. The second inorganic insulation layer 17 (thickness: for example, 70 nm or more and 300 nm or less) may be formed of a silicon nitride (SiNx) film, a silicon oxide (SiOx) film, a silicon oxynitride (SiOxNy; x>y) film, a silicon nitride oxide (SiNxOy; x>y) film, or the like.

### TFT Structure

The DMX circuit TFT illustrated in FIG. 4 is a channel etch type TFT. In the channel etch type TFT, an etch stop layer is not formed on the channel region, and the lower surface of the end on the channel side of the source and drain electrodes is disposed to be in contact with the upper surface of the oxide semiconductor layer. The channel etch type TFT is formed, for example, by forming a conductive film for source/drain electrodes on the oxide semiconductor layer and performing source/drain separation. In the source/drain separation, the surface portion of the channel region may be etched.

The structure of the DMX circuit TFT of the present embodiment is not limited to the illustrated example. The DMX circuit TFT may have an etch stop structure having an etch stop covering the channel region. As the etch stop layer, for example, an insulation layer containing oxygen such as a SiO₂ layer can be used. In the TFT having the etch stop structure, the end portions on the channel side of the source/drain electrodes are located on, for example, the etch stop layer. The etch stop type TFT is formed, for example, by forming a conductive film for source/drain electrodes on the semiconductor layer and the etch stop layer and performing source/drain separation, after forming an etch stop layer covering a portion of the upper surface of the semiconductor layer which is a channel region. Furthermore, the DMX circuit TFT of the present embodiment may have a top contact structure in which the source/drain electrodes are in contact with the upper surface of the semiconductor layer, or may have a bottom contact structure in contact with the lower surface of the semiconductor layer.

### Oxide Semiconductor

The oxide semiconductor that is included in the oxide semiconductor layers may be an amorphous oxide semiconductor and may be a crystalline oxide semiconductor that has a crystalline portion. As the crystalline oxide semiconductor, a polycrystalline oxide semiconductor, a micro-crystalline oxide semiconductor, a crystalline oxide semiconductor in which a c-axis aligns roughly vertically with a layer surface, or the like is given.

The oxide semiconductor layer may have a two- or greater-layered structure. In a case where the oxide semiconductor layer has a multi-layered structure, the oxide semiconductor layer may include a non-crystalline oxide semiconductor layer and a crystalline oxide semiconductor layer. Alternatively, the oxide semiconductor layer may include multiple crystalline oxide semiconductor layers that have different crystal structures. Furthermore, the oxide semiconductor layer may include multiple non-crystalline oxide semiconductor layers. In a case where the oxide semiconductor layer has a two-layered structure in which an upper layer and a lower layer are included, it is preferable that an energy gap of an oxide semiconductor that is contained in the upper layer is set to be greater than an energy gap of an oxide semiconductor that is contained in the lower layer. However, in a case where a difference in the energy gap between the upper and lower layers is comparatively small, the energy gap of the oxide semiconductor in the lower layer may be set to be greater than the energy gap of the oxide semiconductor in the upper layer.

Materials and structures of the non-crystalline oxide semiconductor layer and each of the crystalline oxide semiconductors described above, a film formation method, a structure of the oxide semiconductor that has a multi-layered structure, and the like, for example, are described in Japanese Unexamined Patent Application Publication No. 2014-007399. For reference, the entire contents of Japanese Unexamined Patent Application Publication No. 2014-007399 are incorporated in the present specification by reference.

The oxide semiconductor layer, for example, may include at least one type of metal element among In, Ga, and Zn. In the present embodiment, the oxide semiconductor layer, for example, contains an In—Ga—Zn—O-based semiconductor (for example, oxide indium gallium zinc). The In—Ga—Zn—O-based semiconductor here is a ternary oxide material that consists of Indium (In), Gallium (Ga), and Zinc (Zn). A ratio (a composition ratio) among In, Ga, and Zn is not particularly limited. Examples of the ratio include In:Ga:Zn=2:2:1, In:Ga:Zn=1:1:1, In:Ga:Zn=1:1:2, and the like. This oxide semiconductor layer can be formed from an oxide semiconductor film that contains an In—Ga—Zn—O-based semiconductor.

The In—Ga—Zn—O-based semiconductor may be amorphous and may be crystalline. A crystalline in—Ga—Zn—O-based semiconductor in which a c-axis aligns roughly vertically with a layer surface is preferable as a crystalline In—Ga—Zn—O-based semiconductor.

It is noted that a crystal structure of the crystalline In—Ga—Zn—O-based semiconductor, for example, is disclosed in Japanese Unexamined Patent Application Publication Nos. 2014-007399, 2012-134475, and 2014-209727, which are described above, and other publications. For reference, the entire contents of Japanese Unexamined Patent present Nos. 2012-134475 and 2014-209727 are incorporated in the present specification by reference. A TFT that has an In—GA—Zn—O-based semiconductor layer has high mobility (which is more than 20 times higher than that of an a-Si TFT) and a small amount of leak current (which is less than one-hundredth of that of the a-Si TFT). Because of this, the TFT is suitably used as a drive TFT (for example, a TFT that is included in a drive circuit which is provided on the same substrate as a display area, in the vicinity of the display area that includes multiple pixels) and a pixel TFT (a TFT that is provided in a pixel).

The oxide semiconductor layer may contain any other oxide semiconductor instead of the In—Ga—Zn—O-based semiconductor. For example, an In—Sn—Zn—O-based semiconductor (for example, In2O₃—SnO₂—ZnO; InSnZnO) may be contained. The In—Sn—Zn—O-based semiconductor is a ternary oxide material that consists of Indium (In), Tin (Sn), and Zinc (Zn). Alternatively, the oxide semiconductor layer may contain an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, Cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf—In—Zn—O-based semiconductor, an Al—Ga—Zn—O-based semiconductor, a Ga—Zn—O-based semiconductor, or the like.

In the present embodiment, the oxide semiconductor TFT is used as the DMX circuit TFT. However, a TFT having an active layer made of a semiconductor other than the oxide semiconductor may be used. The DMX circuit TFT may be, for example, an amorphous silicon semiconductor TFT, a crystalline silicon semiconductor TFT, or the like.

### INDUSTRIAL APPLICABILITY

According to the present invention, the embodiments can suitably find application in an active matrix substrate that has a demultiplexer circuit which is monolithically formed. This active matrix substrate finds application in display devices, such as liquid crystal display devices, organic electroluminescence (EL) display devices, and inorganic electroluminescence display devices, image capturing apparatuses such as image sensor devices, and various electronic devices, such as image input devices, fingerprint reading devices, and semiconductor memories.

### REFERENCE SIGNS LIST

1 substrate
3 lower gate electrode
3e1, 3e2 edge portion of lower gate electrode
5 gate insulation layer
7 oxide semiconductor layer
7c channel region
7d drain contact area
7s source contact area
8 source electrode
8e1, 8e2 source edge portion
9e1, 9e2 drain electrode
10 thin-film transistor (DMX circuit TFT)
11 inorganic insulation layer
14 upper gate electrode
14e1, 14e2 edge portion of upper gate electrode
70 contact portion
100 unit circuit
200, 200A, 200B, 300, 400 sub circuit
1000 active matrix substrate
DL channel length direction
DW channel width direction
DR display area
FR non-display area
GD gate driver
SD source driver
PIX pixel area
PE pixel electrode
GL gate bus line
SL source bus line
B, B1 TO B3 branch wiring line
C, C1 to C3 control signal branch line
DO video signal line
DMX, DMX_A, DMX_B, DMX_C, DMX_D demultiplexer circuit
SW, SW1 TO SW3 control signal trunk line
Ta, Tb, Tc, T1a, T1b, T1c, T2a, T2b, T2c thin-film transistor (DMX circuit TFT)
u1 first unit circuit formation area
u2 second unit circuit formation area
us connection area

1. An active matrix substrate that has a display area which includes multiple pixels and a non-display area provided in a vicinity of the display area, the active matrix substrate comprising:
a substrate;
a demultiplexer circuit (DMX circuit) disposed in the non-display area and supported on the substrate;
a plurality of source bus lines that extends in a first direction in the display area; and
a plurality of gate bus lines that extends in a second direction intersecting the first direction, wherein
the demultiplexer circuit includes a plurality of unit circuits and a plurality of control signal trunk lines,
each of the plurality of unit circuits distributes a video signal from one of a plurality of video signal lines to n (n is an integer of 2 or more) source bus lines of the plurality of source bus lines,
each of the plurality of unit circuits includes at least n DMX circuit thin-film transistors (TFTs), n branch wiring lines connected to the video signal line, and the n source bus lines,
each of the DMX circuit TFTs includes a lower gate electrode, a semiconductor layer disposed on the lower gate electrode with a gate insulation layer in between, a source electrode and a drain electrode electrically connected to the semiconductor layer, and an upper gate electrode disposed on the semiconductor layer with an insulation film in between,
one of the upper gate electrode and the lower gate electrode is a front gate electrode to which a control signal is supplied from one of the plurality of control signal trunk lines, and another of the upper gate electrode and the lower gate electrode is a back gate electrode to which a signal different from the control signal is supplied, and
the drain electrode is electrically connected to one of the n source bus lines, the source electrode is electrically connected to one of the n branch wiring lines, and the back gate electrode is electrically connected to the video signal line.

2. The active matrix substrate according to claim 1, wherein
each of the plurality of unit circuits further includes n control signal branch lines and each of the n control signal branch lines is electrically connected to one of the plurality of control signal trunk lines,
the demultiplexer circuit includes a plurality of sub circuits,
each of the sub circuits includes at least a first unit circuit and a second unit circuit among the plurality of unit circuits, and
in each of the sub circuits, the n control signal branch lines in the first unit circuit and the second unit circuit are common.

3. The active matrix substrate according to claim 2,
wherein in each of the sub circuits, the n source bus lines of the first unit circuit and the n source bus lines of the second unit circuit are alternately arranged one by one in the second direction in the display area.

4. The active matrix substrate according to claim 2, wherein
the front gate electrode of each of the DMX circuit TFTs is a part of one of the n control signal branch lines, the source electrode is a part of one of the n branch wiring lines and the drain electrode is a part of one of the n source bus lines, and
in each of the plurality of unit circuits, the n control signal branch lines, the n branch wiring lines and the n source bus lines all extend in the first direction.

5. The active matrix substrate according to claim 4,
wherein in each of the sub circuits, a first unit circuit forming area where the at least n DMX circuit TFTs of the first unit circuit are formed is positioned between a second unit circuit forming area where the at least n DMX circuit TFT of the second unit circuit are formed and the display area.

6. The active matrix substrate according to claim 4,
wherein in each of the sub circuits, one of the at least n DMX circuit TFTs in the first unit circuit and one of the at least n DMX circuit TFT in the second unit circuit are connected to an identical control signal branch line, and are disposed on the identical control signal branch line at an interval.

7. The active matrix substrate according to claim 4, wherein
the plurality of source bus lines are arranged in the second direction from one end, each of the sub circuits includes a first source bus line, a second source bus line, a third source bus line and a fourth source bus line, which are arranged at an Nth(N is a natural number) column, an (N+1)th column, an (N+2)th column, and an (N+3)th column from the one end, respectively,
the first source bus line and the third source bus line are electrically connected to one of the plurality of video signal lines via the first unit circuit, and
the second source bus line and the fourth source bus line are electrically connected to another one of the plurality of video signal lines via the second unit circuit.

8. The active matrix substrate according to claim 7,
wherein in each of the sub circuit, when viewed in a direction normal to the substrate, one of the at least n DMX circuit TFTs of the first unit circuit is disposed between the second source bus line and the fourth source bus line.

9. The active matrix substrate according to claim 1,
wherein each of the at least n DMX circuit TFTs includes a plurality of TFTs arranged in the first direction, and connected in parallel to each other.

10. The active matrix substrate according to claim 9,
wherein a back gate electrode is common to the plurality of TFTs, and when viewed in a direction normal to the substrate, the back gate electrode in common extends in the first direction.

11. The active matrix substrate according to claim 4, wherein
the plurality of control signal trunk lines includes n first control signal trunk lines and n second control signal trunk lines, and each of the n first control signal trunk lines is supplied with a control signal identical with a control signal of one of the n second control signal trunk lines, and
the n control signal branch lines in a part of the plurality of unit circuits are electrically connected to the n first control signal trunk lines, and the n control signal branch lines in another part of the plurality of unit circuits are electrically connected to the n second control signal trunk lines.

12. The active matrix substrate according to claim 1,
wherein the semiconductor layer is an oxide semiconductor layer.

13. The active matrix substrate according to claim 12,
wherein the oxide semiconductor layer includes an In—Ga—Zn—O-based semiconductor.

14. The active matrix substrate according to claim 13,
wherein the In—Ga—Zn—O-based semiconductor includes a crystalline portion.

15. A demultiplexer circuit comprising:
a plurality of unit circuits; and
a plurality of control signal trunk lines, wherein
each of the plurality of unit circuits distributes a video signal from one of a plurality of video signal lines to n (n is an integer of 2 or more) source bus lines,
each of the plurality of unit circuits includes at least n DMX circuit TFTs, n branch wiring lines connected to the video signal line, and the n source bus lines,
each of the DMX circuit TFTs includes a lower gate electrode, a semiconductor layer disposed on the lower gate electrode with a gate insulation layer in between, a source electrode and a drain electrode electrically connected to the semiconductor layer, and an upper gate electrode disposed on the semiconductor layer with an insulation film in between,
one of the upper gate electrode and the lower gate electrode is a front gate electrode to which a control signal is supplied from one of the plurality of control signal trunk lines, and another of the upper gate electrode and the lower gate electrode is a back gate electrode to which a signal different from the control signal is supplied, and
the drain electrode is electrically connected to one of the n source bus lines, the source electrode is electrically connected to one of the n branch wiring lines, and the back gate electrode is electrically connected to the video signal line.
